(19) United States
(12) Patent Application Publication
(10) Pub. No.: US 2026/0096471 A1
(43) Pub. Date: Apr. 2, 2026

(54) SEMICONDUCTOR DIE CAP AND MANUFACTURING METHOD

(71) Applicant: Texas Instruments Incorporated, Dallas, TX (US)

(72) Inventors: Hung-Yun Lin, Murphy, TX (US); Siva Gurrum, Frisco, TX (US); Sophia Delpak, Richardson, TX (US); Brooke Bernier, Allen, TX (US)

(21) Appl. No.: 18/902,383

(22) Filed: Sep. 30, 2024

(51) Int. Cl. H01L 23/04; H01L 23/10; H01L 23/495

(52) U.S. Cl. CPC H10W 76/12; H10W 70/465; H10W 76/60

(57) ABSTRACT

An electronic device includes a semiconductor die having a side, and a cap including a first portion spaced apart from the side of the semiconductor die to define a cavity over a portion of the side of the semiconductor die, and a second portion attached to the side of the semiconductor die and extending from the side of the semiconductor die to the first portion, wherein one of the first and second portions has an opening.

### BACKGROUND

Mechanical stress can affect the performance of an electronic device through piezoresistive, piezo-electric, and other effects that impact device electrical performance. Mismatched coefficients of thermal expansion (CTE) or components of an electronic device can cause mechanical stress among package elements including a semiconductor die, terminal or bump metallization features of a die (e.g., polyimide, copper, aluminum, solder, etc.), bond wires (e.g., gold, copper, etc.), copper alloy lead frame structures, molding compound, etc. CTE mismatch and its effects can be addressed by isolating a semiconductor die from mechanical stress through wafer-level encapsulation (WLE) or the use of ceramic package substrates, but these solutions increase device cost and manufacturing complexity.

### SUMMARY

In one aspect, an electronic device includes a semiconductor die and a cap including a first portion spaced apart from a side of the semiconductor die to define a cavity over a portion of the side of the semiconductor die, and a second portion attached to the side of the semiconductor die and extending from the side of the semiconductor die to the first portion, wherein one of the first and second portions has an opening.

In another aspect, a system includes a circuit board having a conductive feature, and an electronic device, including a conductive terminal that is soldered to the conductive feature of the circuit board, a semiconductor die having a side, and a cap including a first portion spaced apart from the side of the semiconductor die to define a cavity over a portion of the side of the semiconductor die, and a second portion attached to the side of the semiconductor die and extending from the side of the semiconductor die to the first portion, wherein one of the first and second portions has an opening.

In a further aspect, a method includes forming a patterned sacrificial material layer on a side of a semiconductor wafer, forming a cap with an opening on the patterned sacrificial material layer, removing the patterned sacrificial material layer from under the cap, separating a semiconductor die with the cap from the semiconductor wafer, and packaging the semiconductor die to form an electronic device.

### BRIEF DESCRIPTION OF THE DRAWINGS

FIG. 1 is a partial sectional side elevation view of a semiconductor device with a semiconductor die and a cap.

FIG. 1A is a partial sectional side elevation view of another semiconductor device with a semiconductor die with a front side trench and a cap.

FIG. 1B is a partial sectional side elevation view of another semiconductor device with a semiconductor die and a cap having a die coat film.

FIG. 1C is a partial sectional side elevation view of a semiconductor device with a semiconductor die with a front side trench and a cap with a die coat film.

FIGS. 1D-1I are partial top plan views of example die caps.

FIG. 1J is a partial sectional side elevation view of the die cap of FIG. 1I.

FIG. 2 is a flow diagram of a method of fabricating a semiconductor device.

FIGS. 3-26 show an electronic device undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. Described examples include doped regions of various semiconductor structures which may be characterized as p-doped and/or n-doped regions or portions and include regions that have majority carrier dopants of a particular type, such as n-type dopants or p-type dopants, and such regions or portions should be interpreted as having the conductivity type as n-type or p-type, respectively. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing a semiconductor device such as an integrated circuit. While such examples may be expected to provide various improvements, no particular result is a requirement of the present disclosure unless explicitly recited in a particular claim.

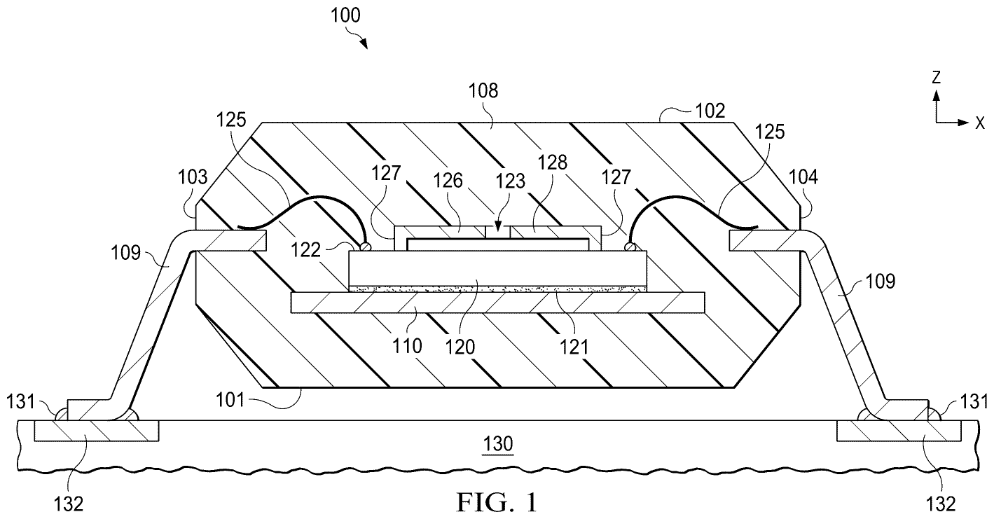

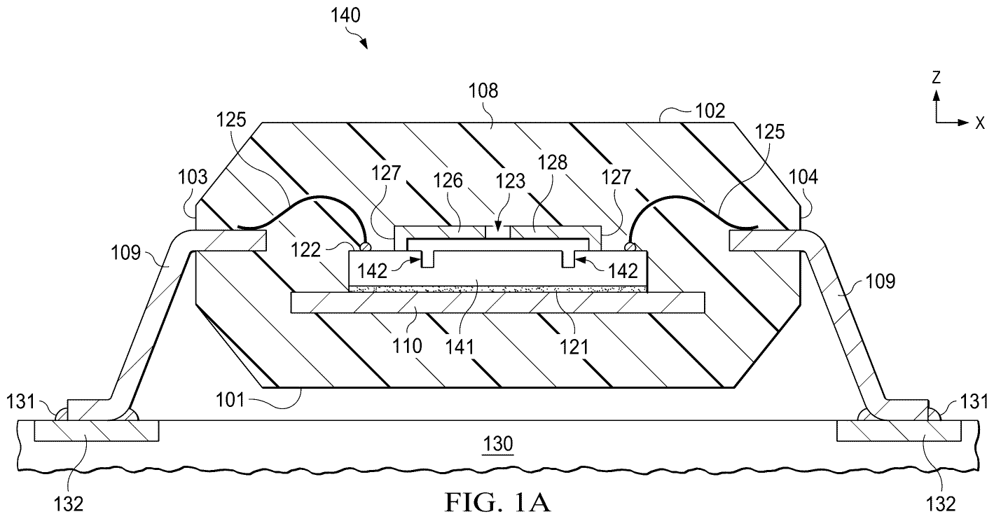

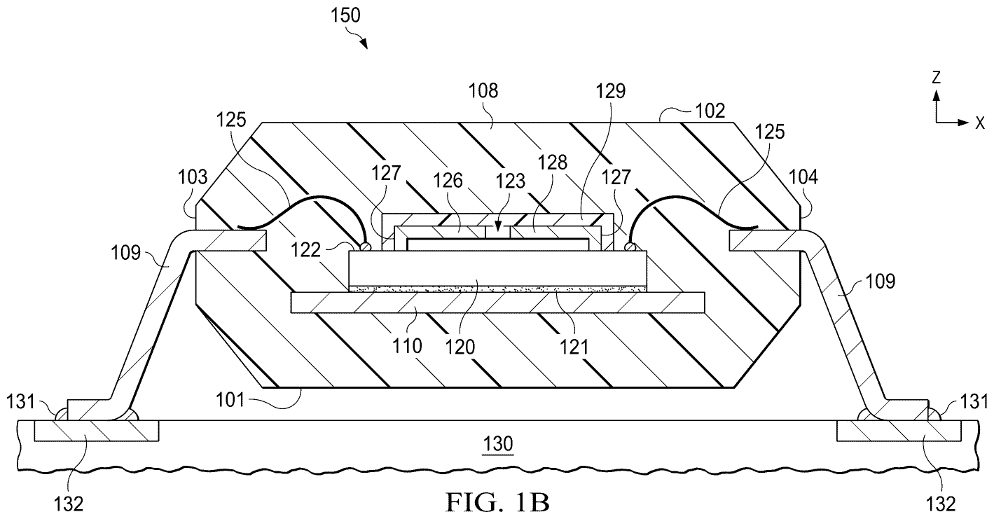

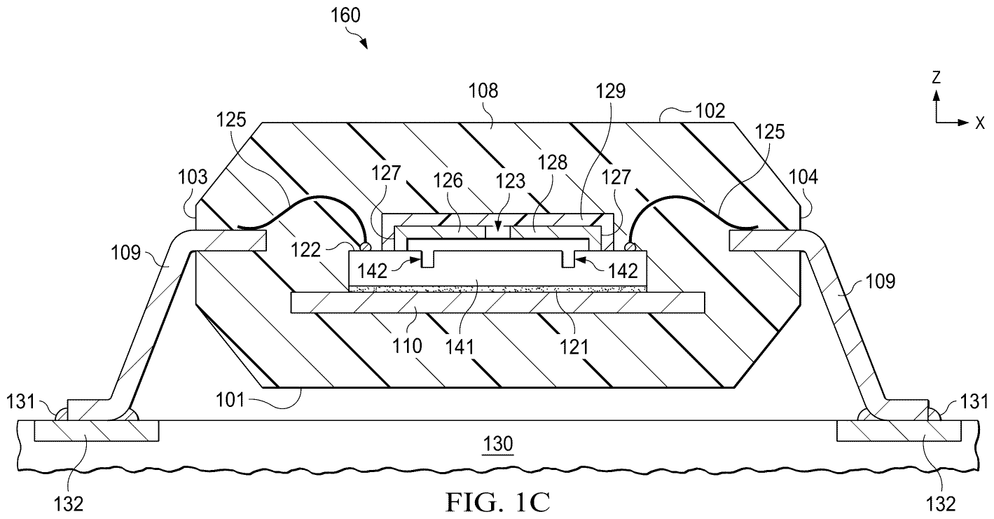

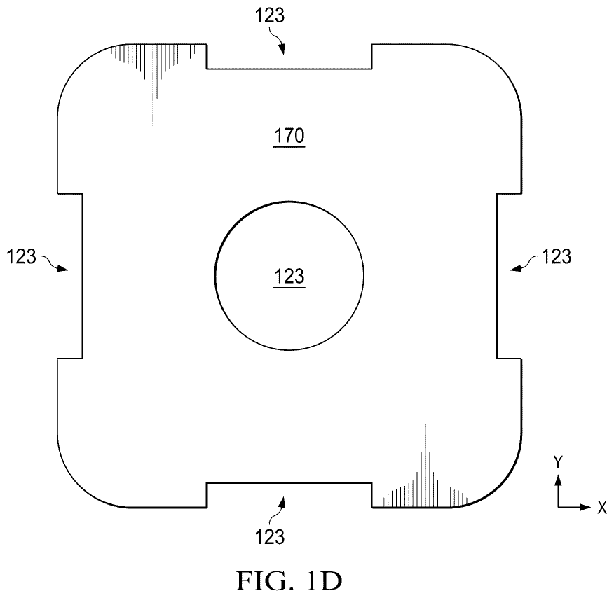

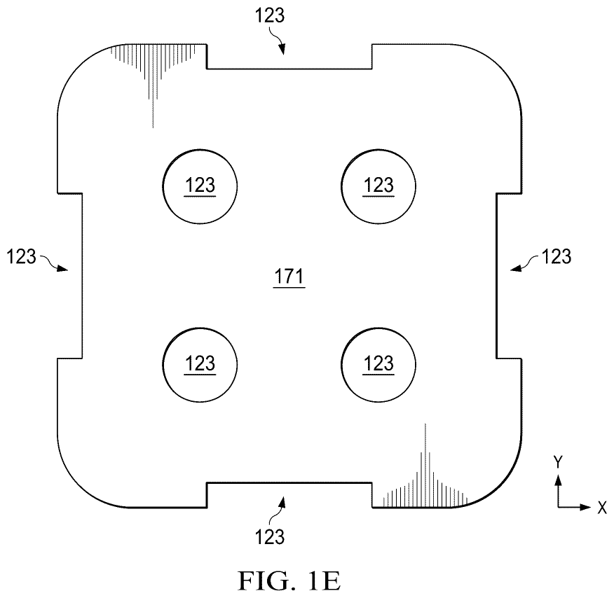

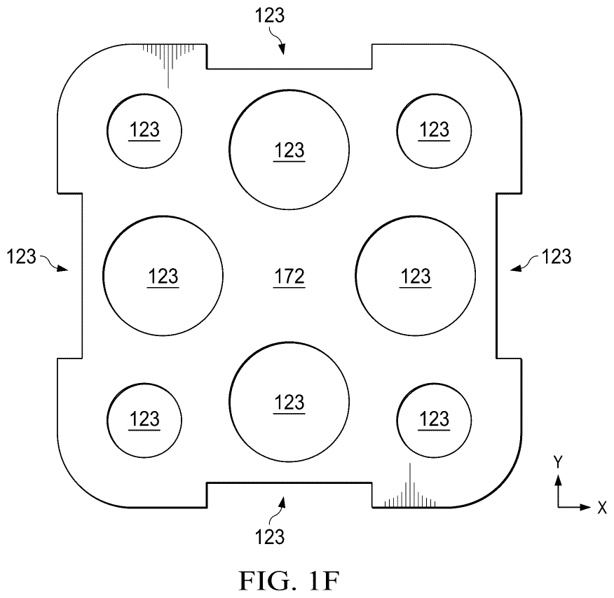

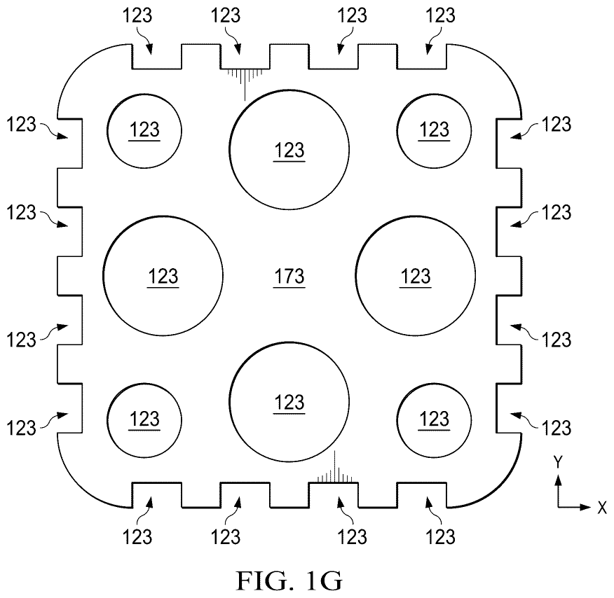

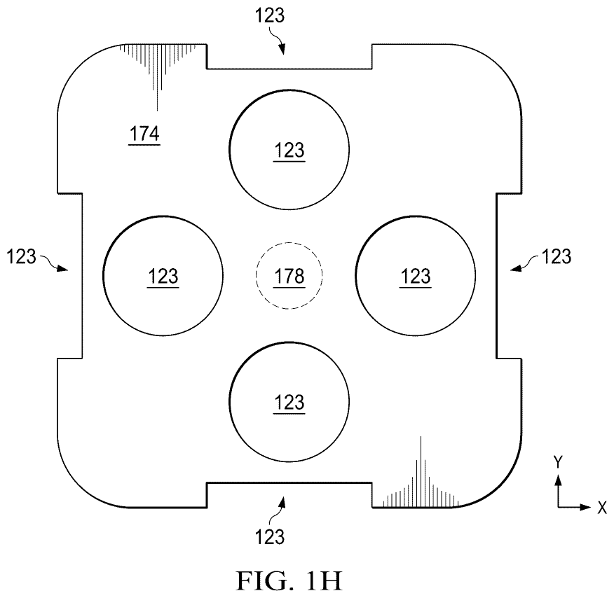

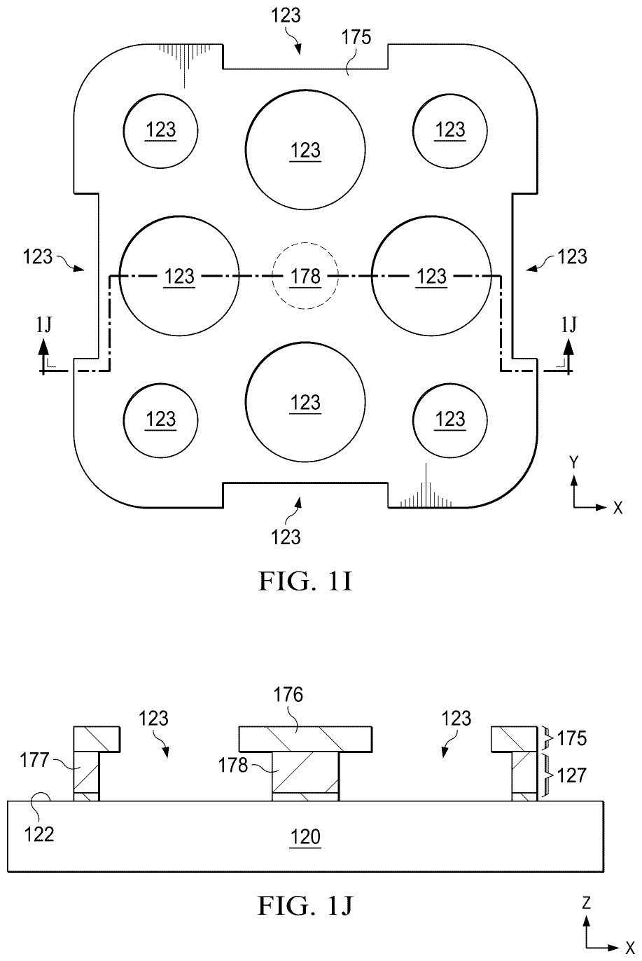

Referring initially to FIGS. 1-1J, FIGS. 1-1C show respective example electronic devices 100, 140, 150, and 160, each having respective semiconductor dies and caps to protect die circuitry from mechanical stress, and FIGS. 1D-1J show example die caps. The electronic devices 100 and 150 (FIGS. 1 and 1B) each have an instance of a semiconductor die 120 attached to a die attach pad 110 by a die attach film adhesive 121, as well as a respective instance of a cap 126 (e.g., also referred to as a die cap) that extends over a portion of a front or top side 122 of the semiconductor die 120, where the die cap 126 includes one or more openings or holes 123. The electronic devices 140 and 160 (FIGS. 1A and 1C) each have an instance of a semiconductor die 141 having a bottom or backside attached to a die attach pad 110 by a die attach film adhesive 121. The semiconductor die 141 in these examples also has one or more front or top side trenches 142, as well as an instance of the cap 126 that extends over a portion of the front or top side 122 of the semiconductor die 141. The electronic devices 150 and 160 of FIGS. 1B and 1C further include a seal film 129 that seals one or more openings 123 of the die cap 126.

The electronic devices 100, 140, 150, and 160 are illustrated in example positions or orientations in a three-dimensional space with respective first, second, and third mutually orthogonal directions X (FIGS. 1-1J), Y (FIGS. 1D-1I), and Z (FIGS. 1-1C and 1J). The electronic devices 100, 140, 150, and 160 include opposite first and second (e.g., bottom and top) sides 101 and 102 (e.g., FIG. 1) that are spaced apart from one another along the third direction Z. The electronic devices 100, 140, 150, and 160 also includes third and fourth sides 103 and 104 that are spaced apart from one another along the first direction X.

The individual electronic devices 100, 140, 150, and 160 include conductive metal leads 109 and a die attach pad 110, with a package structure 108 that encloses the die attach pad 110, at least a portion of the cap 126, the semiconductor die 120, 141 and interior portions of the leads 109. In other implementations, the semiconductor die 120, 141 can be supported on other suitable support structures such as a single or multilevel package substrate (not shown). The example electronic devices 100, 140, 150, and 160 include bond wires 125 coupled to corresponding conductive features on the front side 122 of the semiconductor die 120, 141. The bond wires 125 provide electrical connections between the semiconductor die 120, 141 and one or more leads 109 or other components of the device. In other implementations, different forms of electrical interconnections can be used, such as flip chip solder connections between conductive metal pillars or other terminals of the semiconductor die 120, 141 and conductive features of a single or multilevel package substrate (not shown), alone or in combination with bond wire connections to provide desired electrical connections from between components of the electronic device and the leads 109.

The electronic devices 100, 140, 150, 160 are shown in FIGS. 1-C in a system application with a circuit board 130 having one or more conductive features 132, with corresponding conductive metal leads 109 of the respective electronic devices 100, 140, 150, 160 attached to the corresponding conductive features 132 by solder 131. In other system applications, the electronic devices 100, 140, 150, 160 can be installed into sockets of a host circuit board or system (not shown).

The instances of the example die cap 126 in the electronic devices 100, 140, 150, and 160 in FIGS. 1-1C includes a first portion 128 that forms a top or lid of the cap 126, as well as a second portion 127 that forms one or more sidewalls of the cap 126. In certain examples, the instances of the cap 126 are or include a metal material, such as nickel. In the illustrated examples, the cap 126 is a substantially rectangular structure with the first portion 128 extending generally in a plane of the first and second directions X (shown in FIG. 1) and Y (e.g., into and out of the page), and the second portion 127 extending along the third direction Z as shown in FIG. 1. The instances of the cap 126 in the examples of FIGS. 1A-1C are similarly constructed.

Other shapes and configurations are possible in other implementations, including nonrectangular structures, linear first and second portions, curved portions, combinations thereof, etc. As shown in the example of FIG. 1, the first portion 128 of the cap 126 is spaced apart from (e.g., above) the top or front side 122 of the semiconductor die 120 along the third direction Z to define a cavity over a portion of the side 122 of the semiconductor die 120. The second portion 127 of the die cap 126 extends along the third direction Z from a portion of the side 122 of the semiconductor die 120 to the first portion 128. In various implementations, one or both of the first and second portions 128, 127 has an opening 123, where the sectional view of FIG. 1 shows a portion of a single opening 123 through the first portion 128.

The electronic devices 140 and 160 of FIGS. 1A and 1C include front side die trenches 142 that extend into the top side 122 of the semiconductor die 141. In certain implementations, the die cap 126 laterally surrounds the trench or trenches 142, and the trench 142 laterally surrounds a protected area of the top side 122 of the semiconductor die 141. This structure combines the presence of the die cap 126 and the trench 142 for enhanced protection or isolation of the protected portion of the semiconductor die 141 against mechanical stress during operation, including stress caused by CTE mismatch between two or more structural features of the packaged electronic devices 140, 160. The electronic devices 100 and 150 of FIGS. 1 and 1B also benefit from stress isolation due to the attachment of the die cap 126 that provides mechanical isolation for a protected portion of the top side 122 of the semiconductor die 120, where the sidewalls or second portion 127 of the cap 126 laterally surround the protected portion of the semiconductor die 120.

In certain implementations of the electronic devices 100 and 140 of FIGS. 1 and 1A, the opening or openings 123 of the die cap 126 can be sized such that little or no plastic mold compound of the package structure 108 enters the cavity under the lid or top first portion 128 of the cap 126 during molding operations. In other implementations (not shown), some molding compound may enter the cavity of the die cap 126 and may even fill the cavity of the die cap 126. The electronic devices 150 and 160 of FIGS. 1B and 1C further include the seal film 129 that helps to seal one or more of the openings 123 of the die cap 126. Any suitable seal film 129 can be used, which facilitates sealing the cavity of the die cap 126. In one example, the seal film 129 is or includes polyimide. The seal film 129 in one example is nonconductive material, which can help electrically isolate die cap 126 from the leads 109 and/or other conductive components or structures of the electronic devices 100, 140. The seal film 129 may further beneficially seal the cavity of the die cap 126 to mitigate or prevent mold compound material of the package structure 108 from entering the cavity of the die cap 126. Whether or not the die cap cavity is sealed, and whether or not any of the mold compound of the package structure 108 (or any included seal film 129) enters all or a portion of the die cap cavity, the die cap 126 helps to isolate the protected circuitry of the semiconductor die 120, 141 from adverse effects associated with mechanical stress, such as those induced by device structure CTE mismatch.

The structural or mechanical rigidity of the die cap 126, alone or in further combination with one or both of the die front side trenches 142 and/or the seal film 129 can mitigate adverse mechanical stress-induced effects, including stress caused by CTE mismatch of the various structures of the device. In addition, the die cap 126 provides a cost effective stress isolation solution that can be easily integrated into a semiconductor device fabrication process without significant increase in cost or manufacturing complexity, particularly compared with other stress isolation solutions such as wafer-level encapsulation, ceramic package substrates, etc. In certain examples, moreover, the die cap 126 can include one or more support pillars (e.g., 178 in FIGS. 1H-1J below) that extends upward from the from the top side 122 of the semiconductor die 120, 141 to an interior of the first or lid portion 128 of the die cap 126, which can help improve the structural rigidity of the cap 126 during molding operations as part of a fabrication process and in operation of the electronic device.

FIGS. 1D-1I illustrate several example die caps 170-175 that can be attached to the side 122 of the semiconductor die 120, 141 to provide mechanical stress isolation for circuitry of the semiconductor die 120, 141. The illustrated examples are not limiting, and many other shapes and forms can be implemented, for example, to implement the die cap 126 in the electronic devices 100, 140, 150, 160 of FIGS. 1-1C discussed above. In certain examples, one or both of the top lid or first portion 128 and/or the sidewall or second portion 127 can include one or more openings 123. FIGS. 1D-1I show example top views of the respective die caps 170-175, and FIG. 1J shows a partial sectional side view of the die cap 175 of FIG. 1I installed on the top side 122 of the example semiconductor die 120.

The top lid or first portion 128 of the example die cap 170 of FIG. 1D includes a single fairly large round opening 123 that is laterally spaced apart from a periphery of the first portion 128, as well as large (e.g., along) slot openings 123 in the four sidewalls or second portions 127 of the rectangular shaped die cap 170. Although this example and other illustrated examples include sidewall openings 123 along each of the four lateral sides of the rectangular die cap 170, other examples can have more than one sidewalls, and any number of sidewall openings can be used, with one or more of the sidewalls not including any openings. Moreover, different opening shapes can be used in other implementations.

FIG. 1E shows another example cap 171 with four smaller top openings 123 in the lid or first portion, along with slot openings 123 in the four sidewalls or second portions. Another example rectangular die cap 172 is illustrated in FIG. 1F, which includes four large round openings 123 and four smaller round openings 123 in the lid or first portion, as well as large slot openings 123 in each of the four sidewalls or second portions. A further example die cap 173 in FIG. 1G includes four large and four small round openings 123 in the lid or first portion, in addition to sets of four smaller (e.g., shorter) slot openings 123 in each of the four sidewall or second portions.

FIG. 1H shows another example cap 174 with four large top openings 123 in the lid or first portion, as well as a single large slot opening 123 in each of the four sidewall or second portions. In this example (and those previously described), the sidewalls or second portions of the die cap 174 in FIG. 1H extend from the side 122 of the semiconductor die 120, 141 to a periphery of the first portion 128 (e.g., as shown in the sectional side views of FIGS. 1-1C above). The example die cap 174 in FIG. 1H also includes a support pillar 178 that extends from the top side to an interior of the lid or first portion 128, with the support pillar 178 laterally spaced apart from the sidewalls or second portions 127 of the cap 174. Although a single support pillar 178 is included in the illustrated example die cap 174, more than one support pillars can be included in other implementations.

FIGS. 1I and 1J illustrate a further example die cap 175 that has four large round openings 123 and four smaller round openings 123 in the lid or first portion, as well as large slot openings 123 in the four sidewalls or second portions. This example is similar to the die cap 172 of FIG. 1F, but further includes a single support pillar 178 that extends from the top side to an interior of the lid or first portion 128, and the support pillar 178 is laterally spaced apart from the sidewalls or second portions 127 of the cap 175. Although the illustrated examples provide generally symmetrical positioning of the openings 123 in the first and/or second portions of the die cap, other asymmetrical arrangements of one or more openings can be used in either or both of the first and/or second portions of the cap. Larger openings 123 and/or the use of larger numbers of openings 123 can facilitate removal of sacrificial material initially formed in the prospective cavity under the lid or first portion of the die cap, whereas the use of fewer openings 123 and/or smaller openings can help mitigate or avoid incursion or entry of mold material of the package structure 108 (and/or entry of any included die film 129) into the cavity of the die cap during fabrication processing.

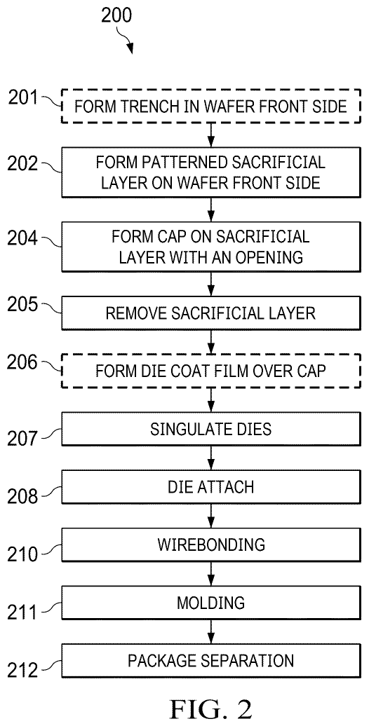

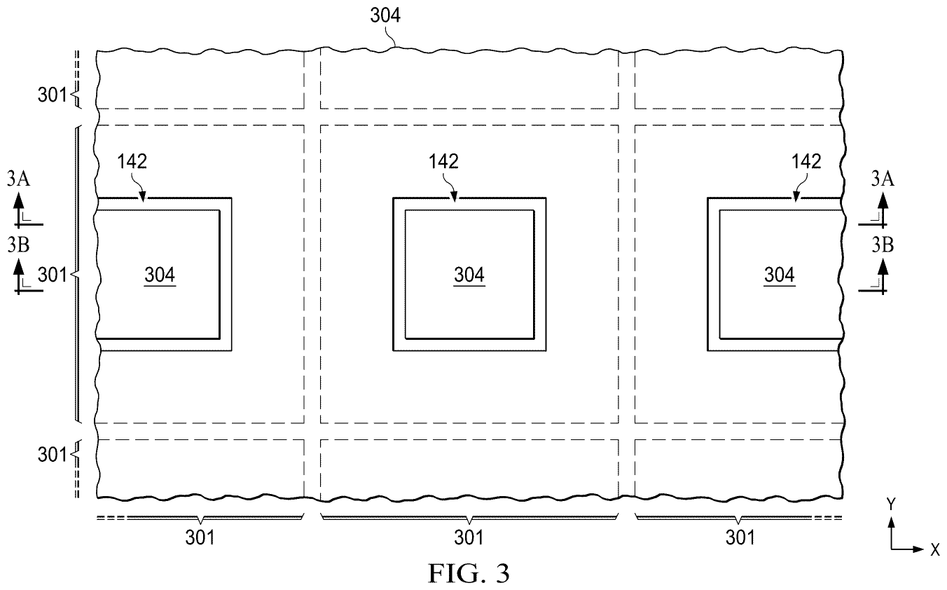

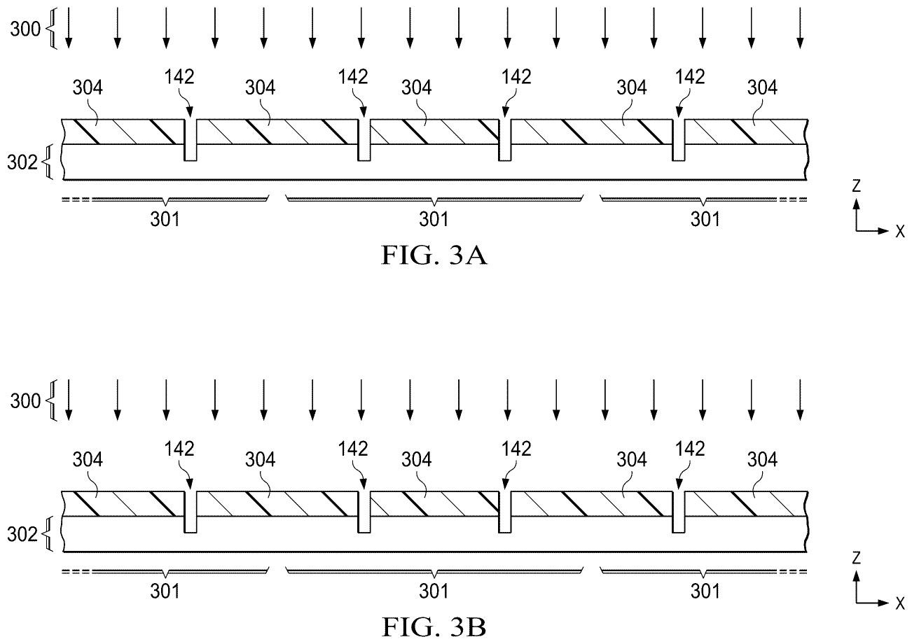

Referring also to FIGS. 2-26, FIG. 2 shows an example method 200 of fabricating a semiconductor device, and FIGS. 3-26 show example electronic devices undergoing fabrication processing according to various implementations of the method 200.

The method 200 begins in one example at 201 with optional trench formation in the front side of a processed semiconductor wafer, such as a silicon wafer, a silicon-over-insulator (SOI) wafer, or other wafer having a silicon or other semiconductor layer with circuitry form thereon and/or therein. FIGS. 3-3B show one example, in which an etch process 300 is performed using an etch mask 304 to form the trenches 142 that extend into the front or top side of a processed wafer 302. These figures and subsequent figures illustrate wafer level processing on multiple prospective die areas or unit areas 301 of the processed wafer 302 prior to die singulation or separation of individual processed semiconductor dies (e.g., dies 120, 141 discussed above) from the starting wafer structure.

FIG. 3 shows a partial top view of a processed wafer 302, FIG. 3A shows a partial sectional side view of the wafer 302 taken along line 3A-3A of FIG. 3, and FIG. 3B shows a partial sectional side view of the wafer 302 taken along line 3B-3B of FIG. 3. The etch process 300 and FIGS. 3-3B forms the trench or trenches 142 and the top side of each unit area 301 of the wafer 302. In one example, each unit area 301 includes a rectangular single trench as best shown in FIG. 3 that extends around (e.g., encircles or laterally surrounds) circuitry of a protected area of the top side of the wafer for each unit area 301, such as a bulk acoustic wave (BAW) resonator circuit during formation of a BAW die, or a sensor or other circuit to be protected against mechanical stress during operation of the ultimately formed electronic device. In other examples, any number and form of one or more trenches can be formed and each unit area 301 of a processed wafer 302 at 201 in FIG. 2. In other implementations (e.g., FIGS. 1 and 1B above), the trench formation at 201 in FIG. 2 can be omitted.

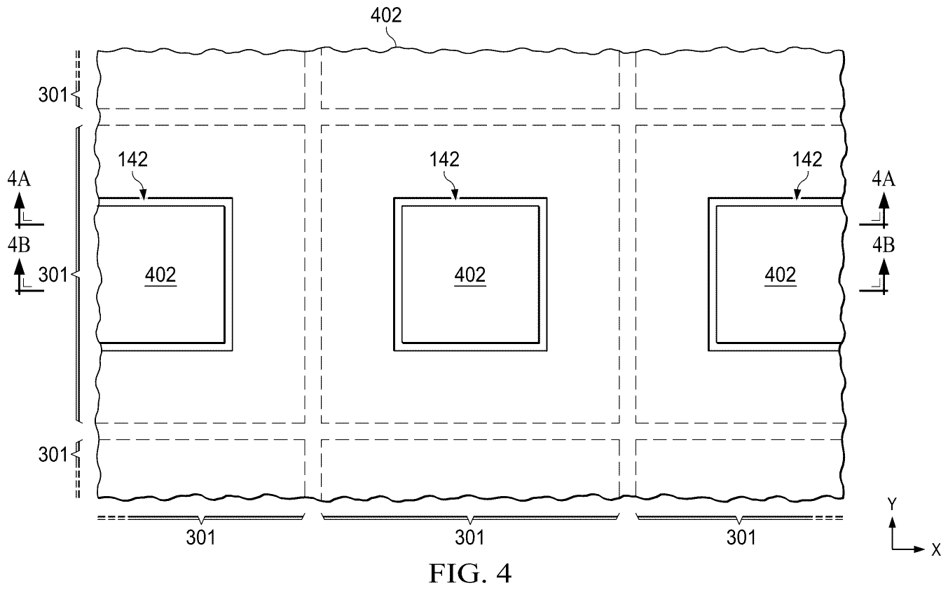

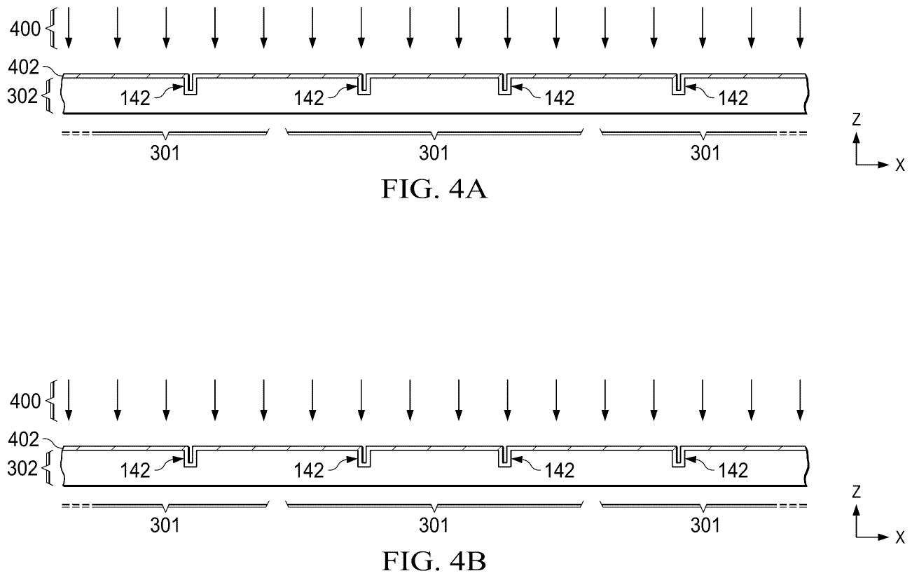

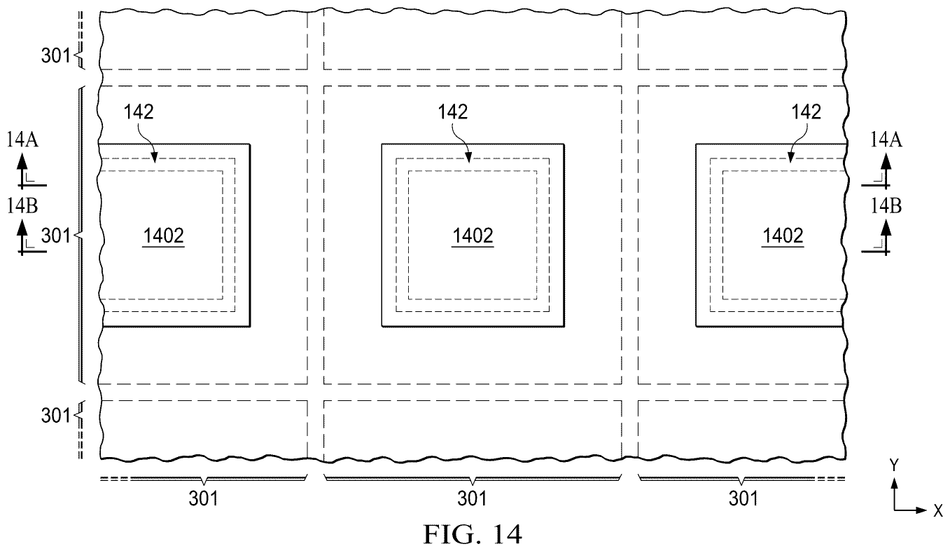

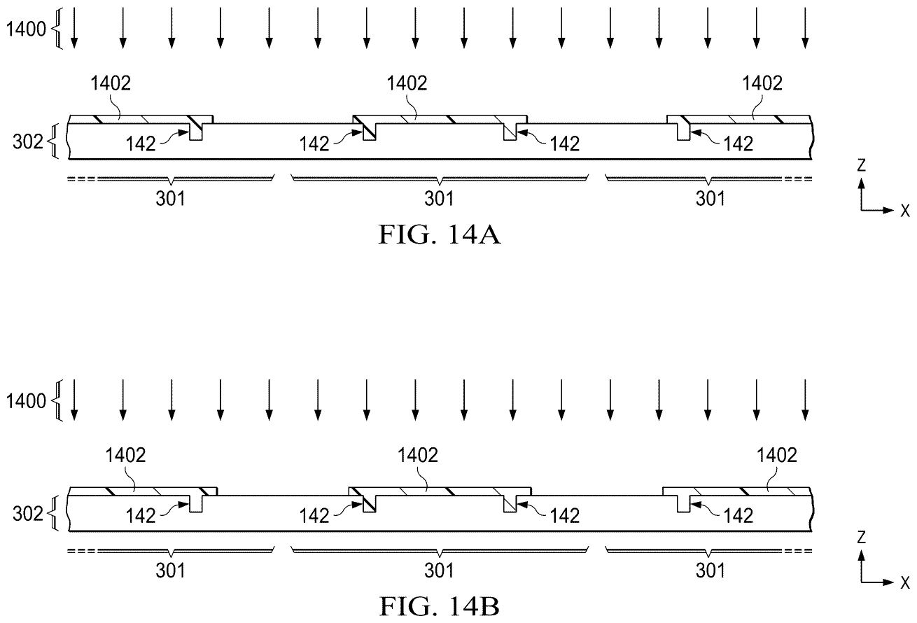

The method 200 continues at 202 in FIG. 2 with forming a patterned sacrificial material layer on the top side of the semiconductor wafer 302. FIGS. 4-12B and 13-26 illustrate fabrication according to one implementation using a copper metal sacrificial material to help formation of the die cap. FIGS. 14-21B show partial fabrication according to another implementation using photo resist sacrificial material in forming the die cap.

FIGS. 4-7B show one example in which a copper sacrificial material layer is formed on the top side of the semiconductor wafer 302. FIGS. 4-4B show one example, in which a deposition process 400 is performed that forms a copper metal seed layer 402 along the top side of the wafer 302 and along the sidewalls and bottom of the previously formed trenches 142. FIG. 4 shows a partial top view of the processed wafer 302 with the metal seed layer 402, FIG. 4A shows a partial sectional side view of the wafer 302 taken along line 4A-4A of FIG. 4, and FIG. 4B shows a partial sectional side view of the wafer 302 taken along line 4B-4B of FIG. 4. In one example, the deposition process 400 includes sputter deposition of copper material without requiring any deposition mask to form a thin layer of copper 402 that extends on the top side of the wafer 302 and in the trenches 142 as shown in FIGS. 4-4B.

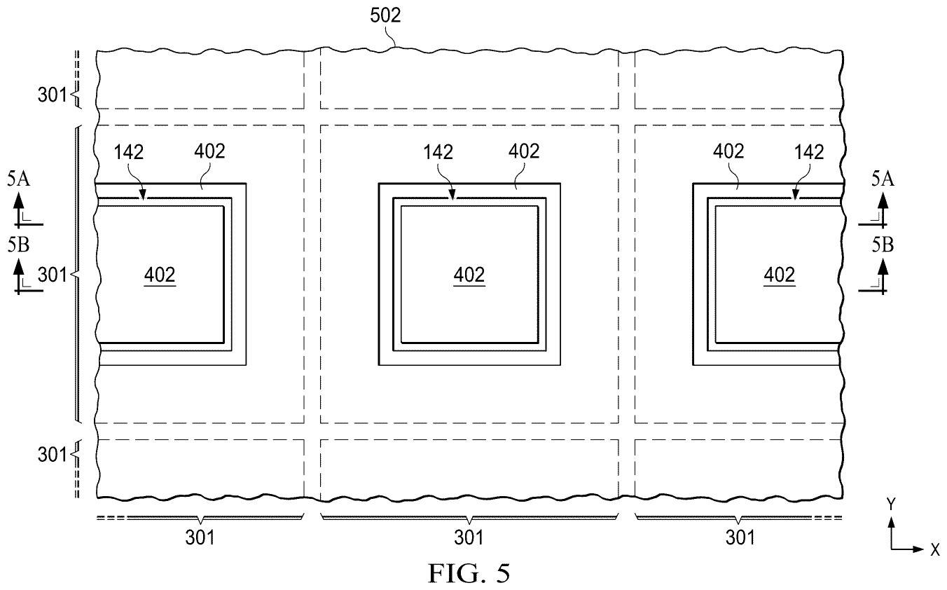

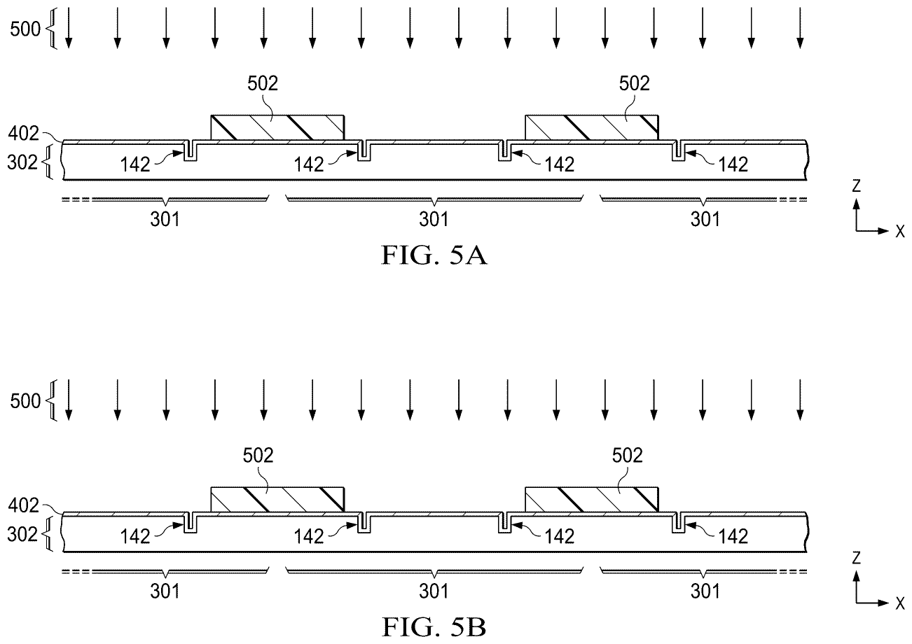

This example continues with deposition and patterning of a deposition mask for forming the sacrificial material layer. FIGS. 5-5B show one example, in which a process 500 is performed that deposits and patterns a deposition mask 502 over the copper seed layer 402 along select portions in each unit area 301 of the top side of the wafer 302. FIG. 5 shows a partial top view of the processed wafer 302 with the formed and patterned mask 502, FIG. 5A shows a partial sectional side view of the wafer 302 taken along line 5A-5A of FIG. 5, and FIG. 5B shows a partial sectional side view of the wafer 302 taken along line 5B-5B of FIG. 5. The deposition mask 502 exposes portions of the copper seed layer 402 in each unit area corresponding to locations for the prospective cavity of the subsequently formed die cap. The patterning of the deposition mask 502 can be adjusted to accommodate any desired pattern for the subsequently formed die cap sidewalls or second portion 127 and any included support pillars 178 as described above.

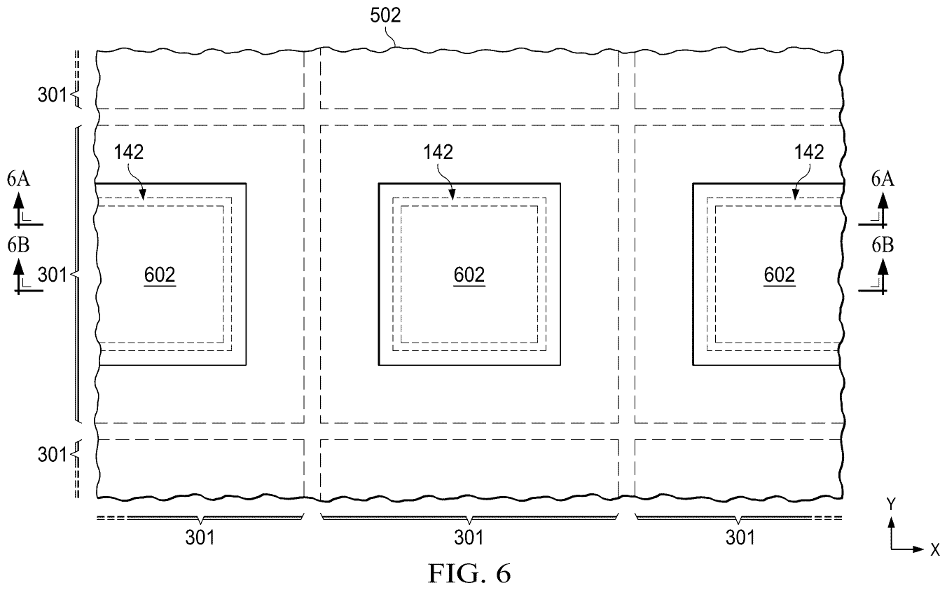

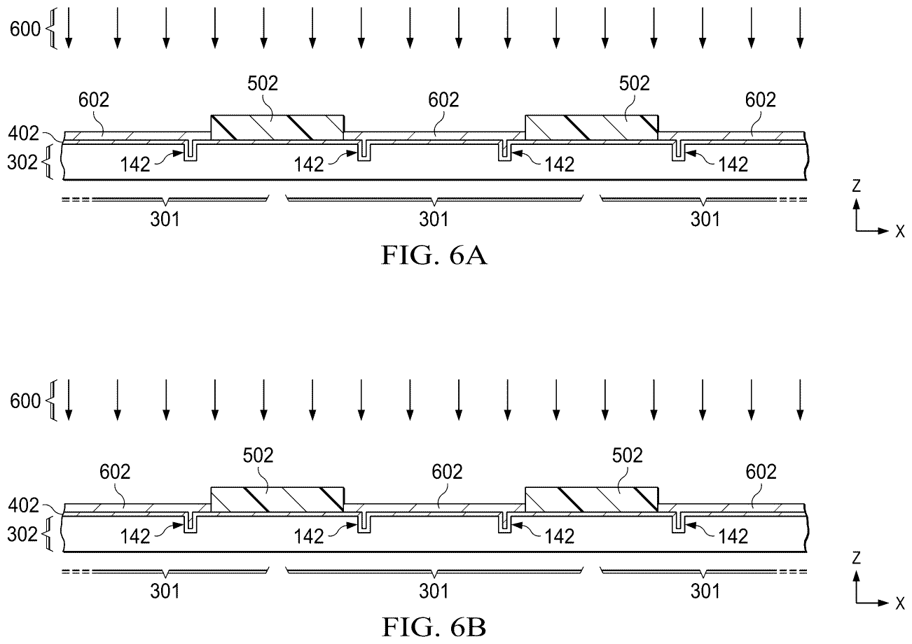

This example continues with a deposition process 600 to form sacrificial material in FIGS. 6-6B. FIG. 6 shows a partial top view of the processed wafer 302 with the sacrificial material 602, FIG. 6A shows a partial sectional side view of the wafer 302 taken along line 6A-6A of FIG. 6, and FIG. 6B shows a partial sectional side view of the wafer 302 taken along line 6B-6B of FIG. 6. In one example, the deposition process 600 is an electroplating process that forms the copper sacrificial material layer 602 over the exposed portions of the seed layer 402 along the top side of the wafer 302 and in the previously formed trenches. The electroplating deposition process 600 is performed in one example to deposit the sacrificial material layer 602 to a thickness corresponding to the desired die cap cavity height along the third direction Z.

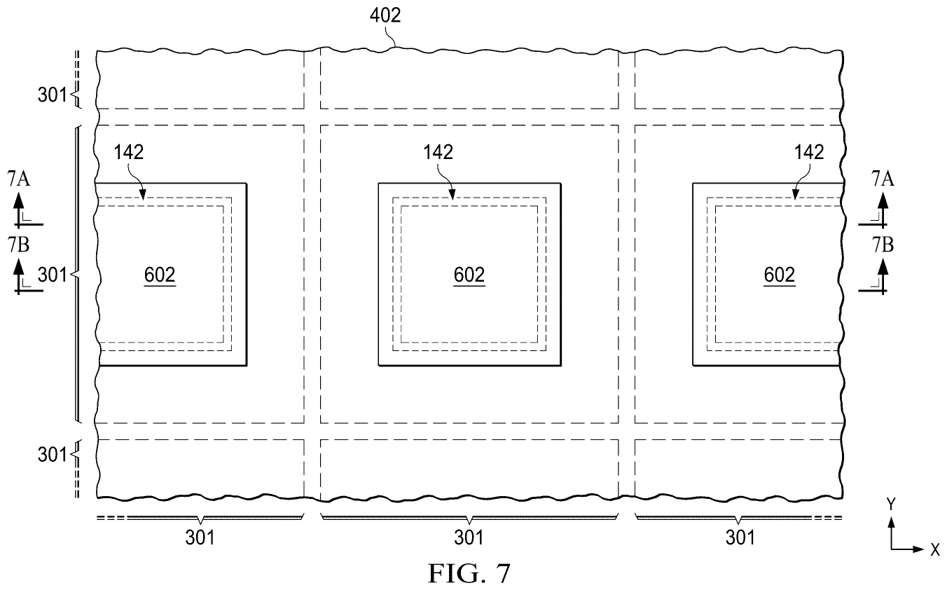

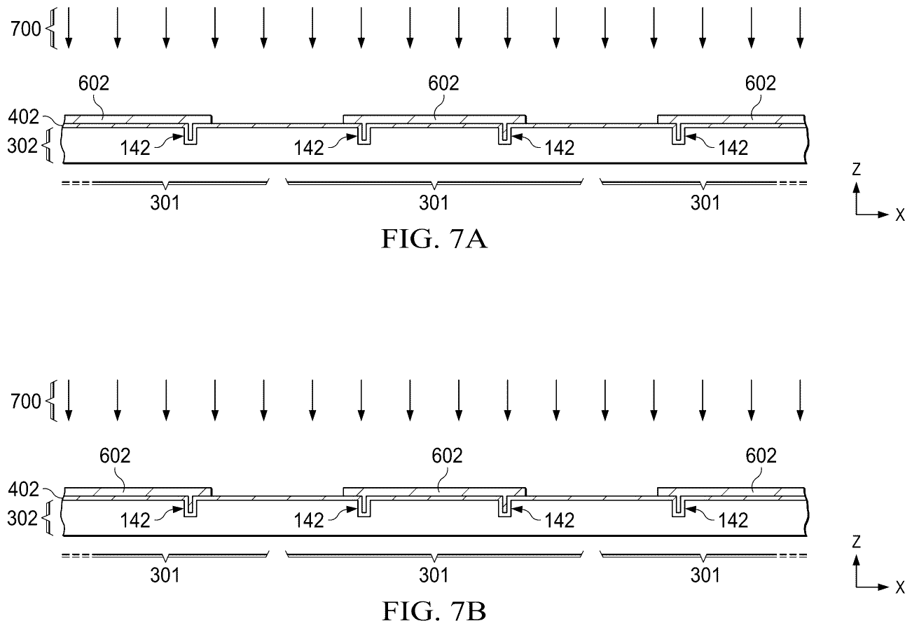

In this example of the sacrificial material layer formation (e.g., at 202 in FIG. 2), the deposition mask 502 is then removed to leave the patterned sacrificial material layer 602 along the top of the semiconductor wafer 302 and extending into any included trenches in each unit area 301 of the wafer 302. FIGS. 7-7B show one example of a photo resist strip process 700, where FIG. 7 shows a partial top view of the processed wafer 302, FIG. 7A shows a partial sectional side view of the wafer 302 taken along line 7A-7A of FIG. 7, and FIG. 7B shows a partial sectional side view of the wafer 302 taken along line 7B-7B of FIG. 7. The mask removal (photo resist strip) process 700 removes the deposition mask and leaves the previously covered portions of the seed layer 402 exposed between the patterned sacrificial material layer 602 along the top side of the wafer 302.

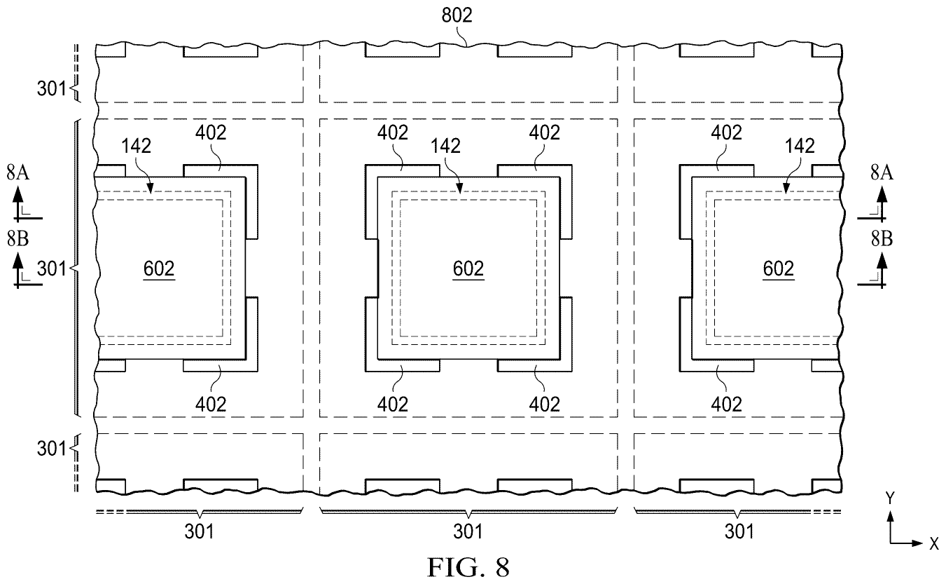

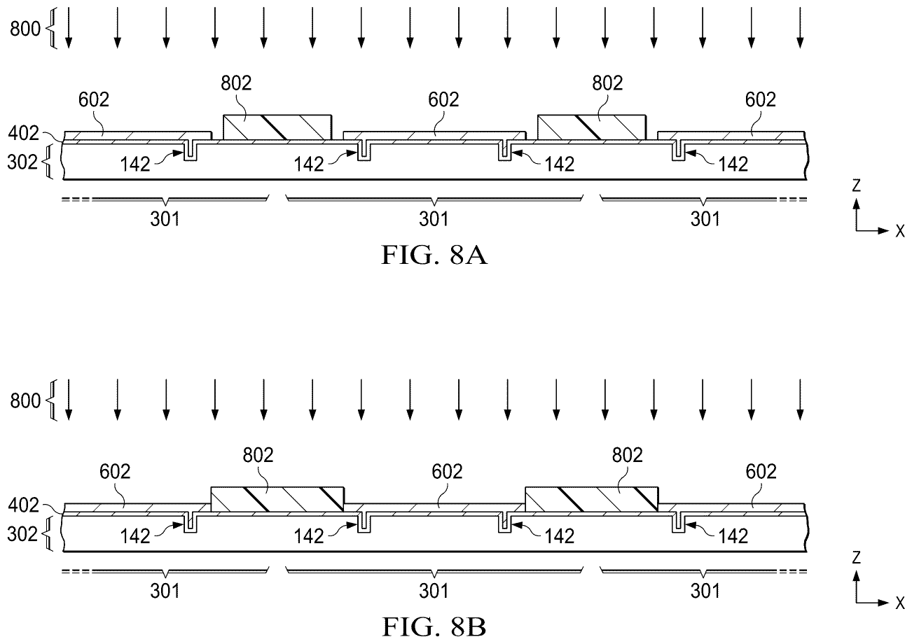

The method 200 continues at 204 in FIG. 2 with formation of the cap 126 over the sacrificial material 602 in each unit area 301 of the wafer 302. FIGS. 8-10B show one implementation using the previously formed copper metal sacrificial material layer 602. FIGS. 8-8B show a first step, in which a mask formation process 800 is performed that deposits and patterns a second deposition mask 802 along select portions of the exposed seed layer 402. FIG. 8 shows a partial top view of the processed wafer 302, FIG. 8A shows a partial sectional side view of the wafer 302 taken along line 8A-8A of FIG. 8, and FIG. 8B shows a partial sectional side view of the wafer 302 taken along line 8B-8B of FIG. 8. The process 800 forms the second deposition mask 802 having different dimensions along the two sectional views of FIGS. 8A and 8B to accommodate the formation of the sidewall openings for the illustrated example die cap, where the portions of the sidewall or second cap portion (e.g., 127 above) are to be wider along the edge portions (FIG. 8A) and slightly narrower in the interior portions where a slot opening 123 is to be formed (FIG. 8B).

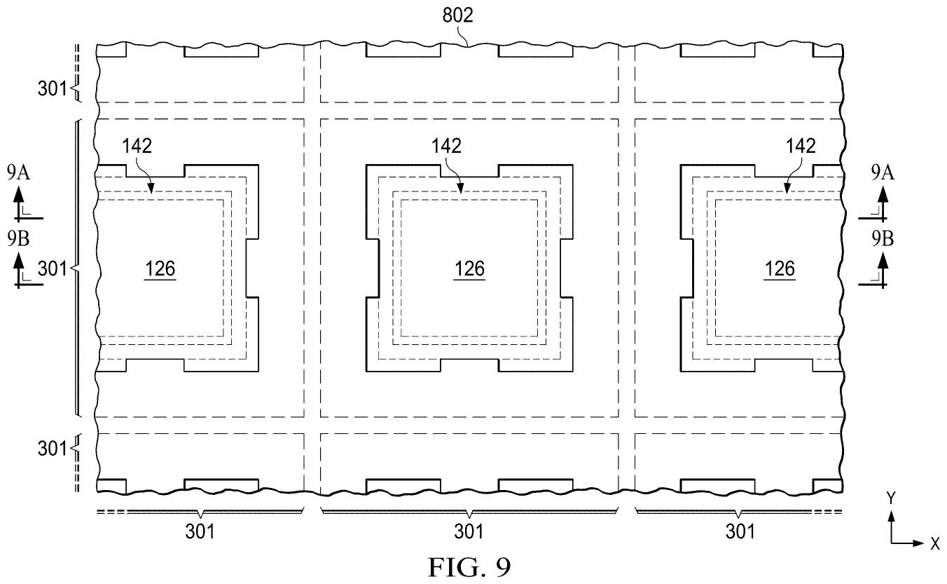

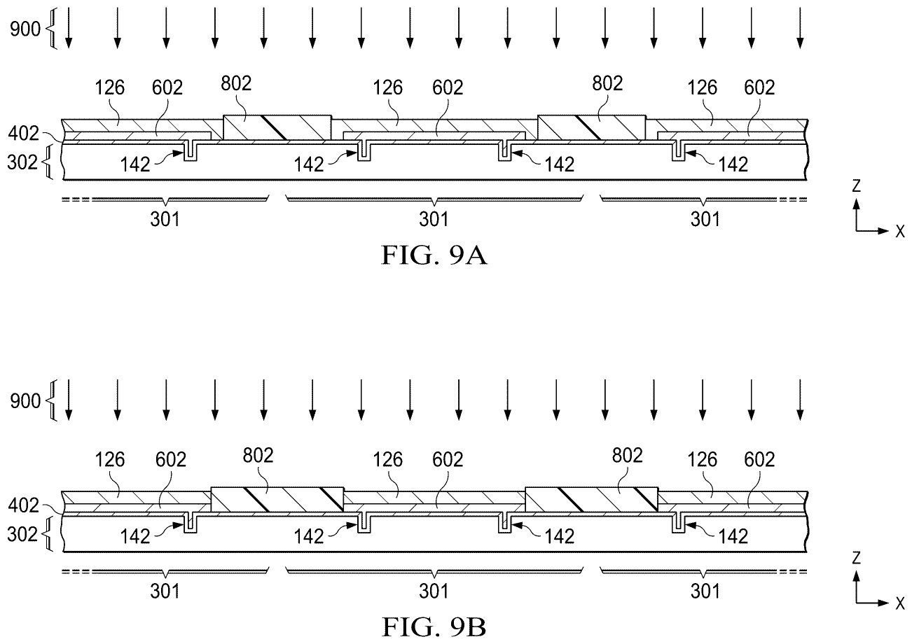

This example continues with another deposition process 900 to form die cap material formation in FIGS. 9-9B. FIG. 9 shows a partial top view of the processed wafer 302, FIG. 9A shows a partial sectional side view of the wafer 302 taken along line 9A-9A of FIG. 9, and FIG. 9B shows a partial sectional side view of the wafer 302 taken along line 9B-9B of FIG. 9. In one example, the deposition process 900 is a second electroplating process or other suitable metal deposition process that forms the nickel cap 126 over the exposed portions of the patterned sacrificial material layer 602 and any portions of the seed layer 402 exposed by the second deposition mask 802. The electroplating deposition process 900 is performed in one example to deposit the first and second portions of the nickel cap 126 to a thickness or respective thicknesses corresponding to the desired die cap thickness along the third direction Z.

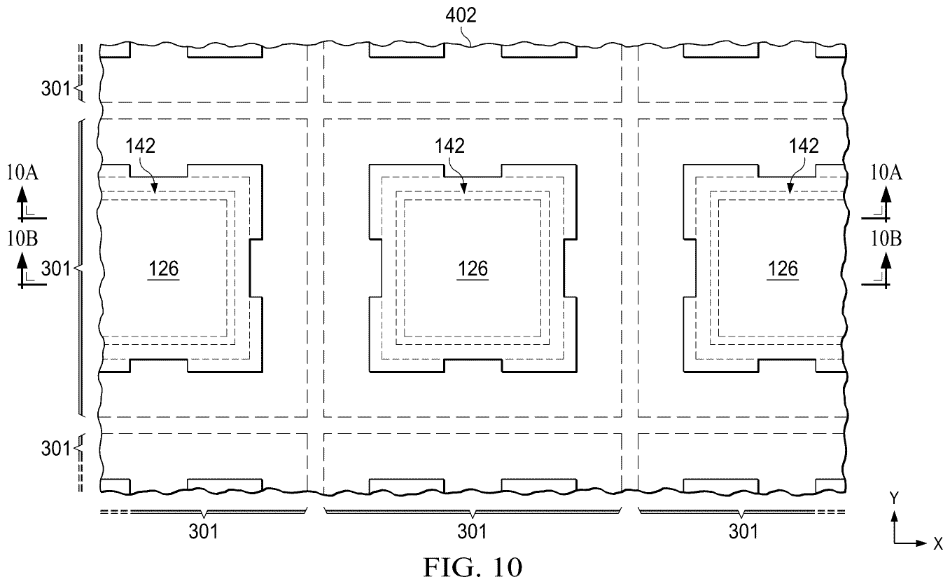

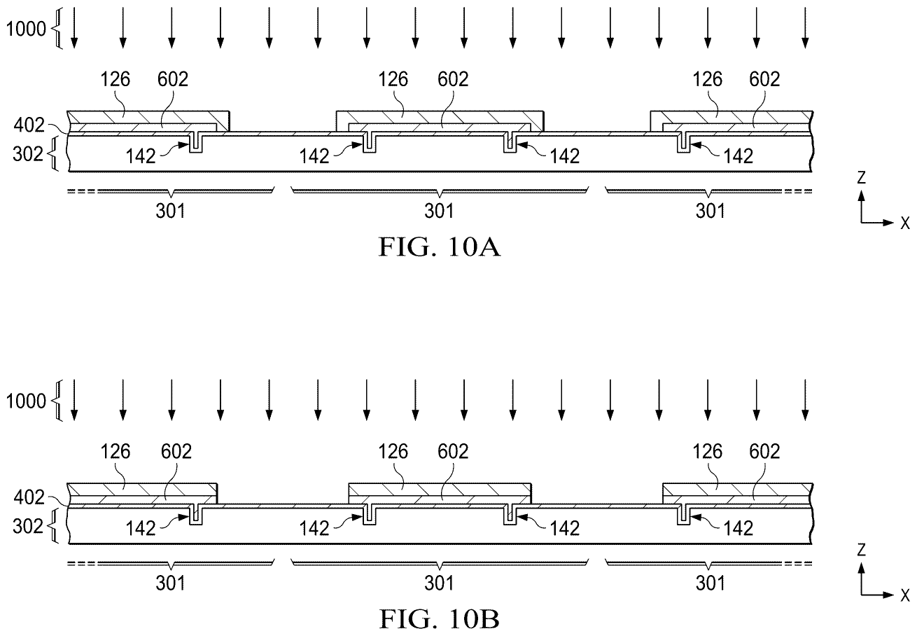

This example of the cap formation (e.g., at 204 in FIG. 2) continues with removal of the second deposition mask 802 by a mask removal process to leave the patterned cap 126 and portions of the sacrificial material layer 602 that are exposed through the opening or openings 123 of the cap 126. FIGS. 10-10B show one example of another photo resist strip process 1000, where FIG. 10 shows a partial top view of the processed wafer 302, FIG. 10A shows a partial sectional side view of the wafer 302 taken along line 10A-10A of FIG. 10, and FIG. 10B shows a partial sectional side view of the wafer 302 taken along line 10B-10B of FIG. 10. The mask removal (photo resist strip) process 1000 removes the second deposition mask and leaves the patterned cap 126 and exposed portions of the sacrificial material layer 602 as well as the previously covered portions of the seed layer 402.

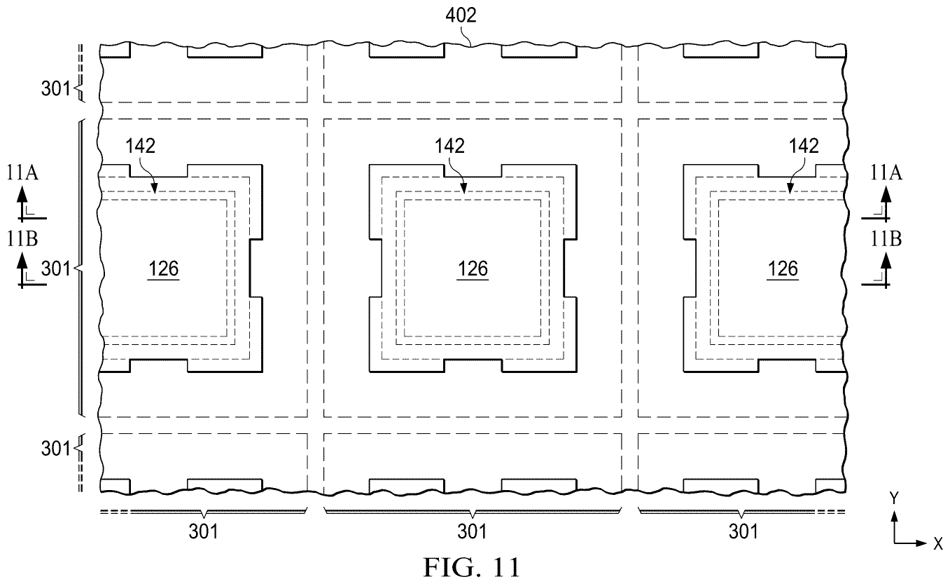

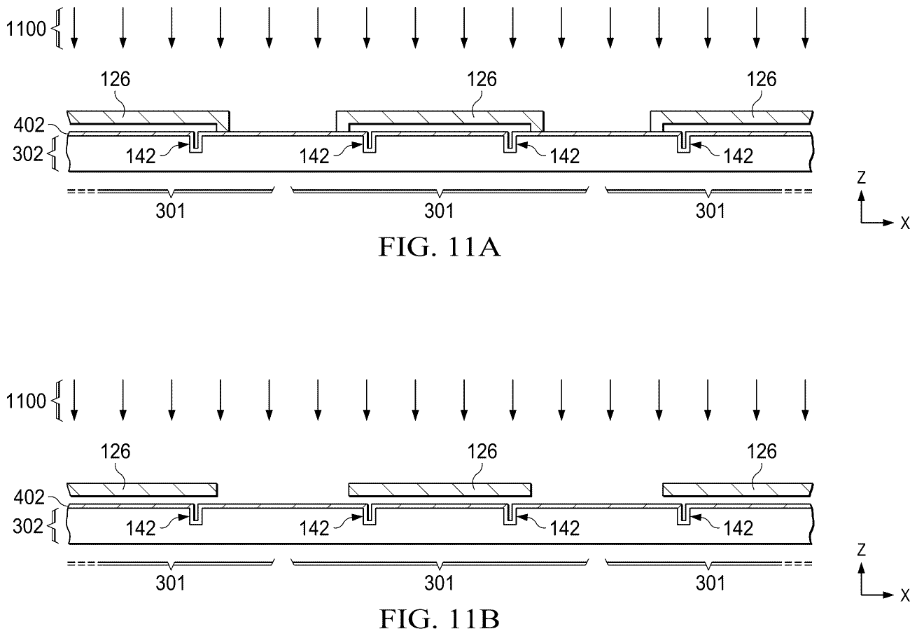

The method 200 continues at 205 in FIG. 2 with sacrificial material removal processing. FIGS. 11-11B show one example of an etch process 1100, where FIG. 11 shows a partial top view of the processed wafer 302, FIG. 11A shows a partial sectional side view of the wafer 302 taken along line 11A-11A of FIG. 11, and FIG. 11B shows a partial sectional side view of the wafer 302 taken along line 11B-11B of FIG. 11. The etch process 1100 in one example is selective to the copper sacrificial material and operates to remove the sacrificial copper from under the cap 126 through the opening or openings 123 of the nickel die cap 126. The process 1100 leaves the electroplated nickel die cap structure 126 with the cavity defined by the space from which the sacrificial copper was removed and the cap 126 includes the openings 123 through the desired portions of the nickel material 126. As discussed above, the sizing, number, and positioning of the opening or openings 123 can be adjusted to facilitate the etch process 1100 in consideration of the final structural rigidity of the cap 126 as well as any considerations related to preventing or mitigating ingress of mold compound of the device package structure (e.g., 108 above) and/or ingress of any included seal film 129.

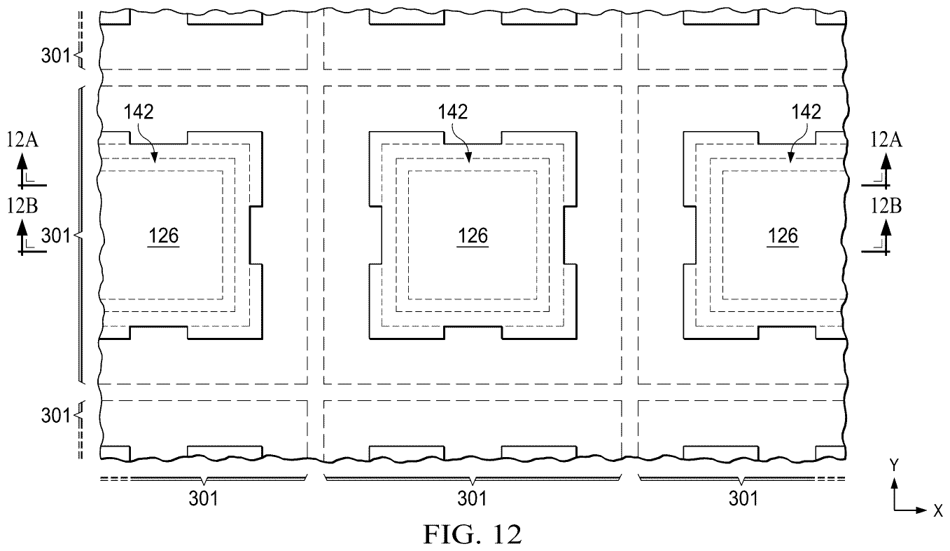

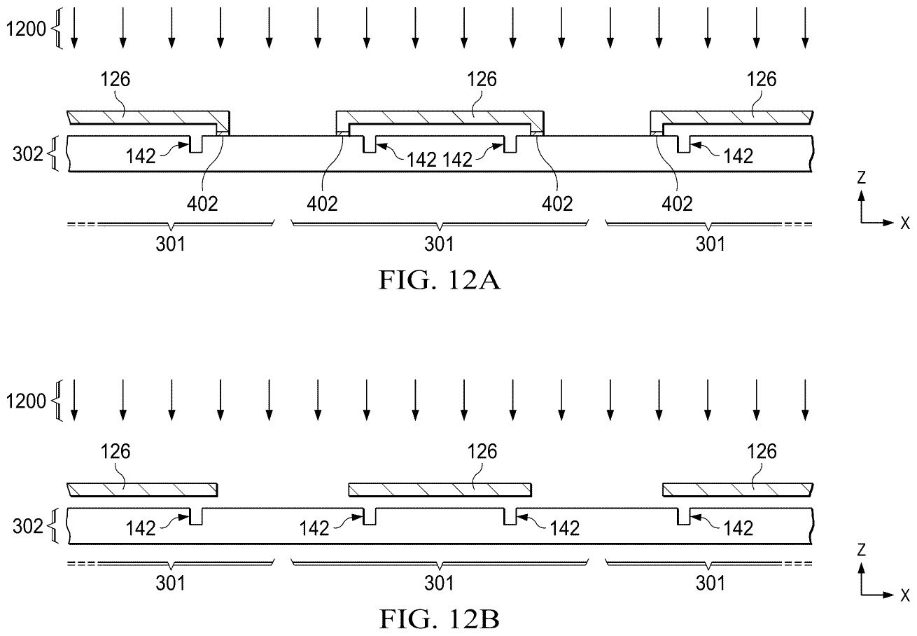

The illustrated example continues in one implementation with etching or other removal of any remaining exposed portions of the seed metal layer 402. FIGS. 12-12B show one example of a seed layer etch process 1200 that removes the seed layer portions 402 between the patterned die caps 126 along the top side of the wafer 302, leaving portions of the seed layer 402 underneath the sidewall or second portions 127 of the cap 126. FIG. 12 shows a partial top view of the processed wafer 302, FIG. 12A shows a partial sectional side view of the wafer 302 taken along line 12A-12A of FIG. 12, and FIG. 12B shows a partial sectional side view of the wafer 302 taken along line 12B-12B of FIG. 12 following the seed layer etch process 1200.

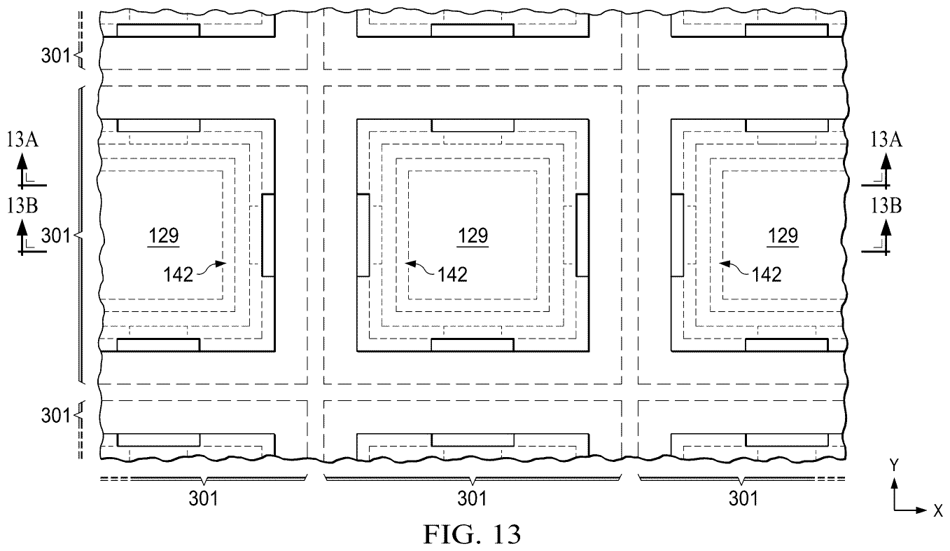

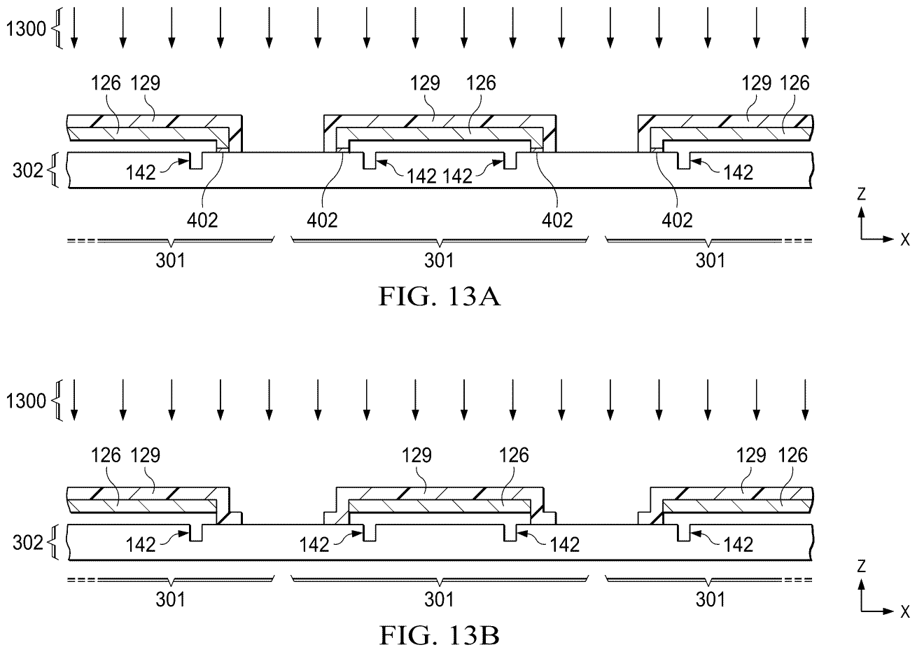

In one implementation, the method 200 continues at 206 in FIG. 2 with optional die coat film formation. FIGS. 13-13B show one example, in which a process 1300 is performed that deposits and patterns or otherwise selectively forms the die coat film 129 over the cap 126 in each unit area 301 of the wafer 302. FIG. 13A shows a partial sectional side view of the wafer 302 taken along line 13A-13A of FIG. 13, and FIG. 13B shows a partial sectional side view of the wafer 302 taken along line 13B-13B of FIG. 13. In one implementation, the die coat film 129 seals the opening or openings 123 of the cap 126. In another implementation, the die coat film formation at 206 can be omitted.

The method 200 continues at 207-212 in FIG. 2 in order to complete the packaged electronic device including separating individual semiconductor dies 120, 141 from the processed wafer 302 and packaging operations as described further below.

Referring now to FIGS. 2 and 14-21B, in another implementation of the method 200 of FIG. 2, the wafer level processing uses photo resist sacrificial material in forming the die cap 126. FIGS. 14-21B illustrate example wafer processing according to this implementation, starting from the above-described wafer 302 with the optional trenches 142 (e.g., as shown in FIGS. 3-3B above). This example includes forming the sacrificial material layer is or includes a photo resist material that is initially formed and patterned (e.g., FIGS. 14-14B) before depositing a metal seed layer. This is in contrast to the above-described first implementation using a copper metal sacrificial material, in which the metal seed layer 402 was formed on the side of the semiconductor wafer 302 before forming 202 the patterned sacrificial material layer 602.

FIGS. 14-14B show one example, in which a sacrificial material formation process 1400 is performed that deposits and patterns a sacrificial material layer 1402, such as a photo resist, along the top side of the wafer 302 and along the sidewalls and bottom of the previously formed trenches 142. FIG. 14 shows a partial top view of the processed wafer 302 with the patterned sacrificial material layer 1402, FIG. 14A shows a partial sectional side view of the wafer 302 taken along line 14A-14A of FIG. 14, and FIG. 14B shows a partial sectional side view of the wafer 302 taken along line 14B-14B of FIG. 14. In one example, the processing 1400 includes depositions followed by patterning of a photo resist material layer to form the sacrificial material layer structures 1402 as shown in FIGS. 14-14B.

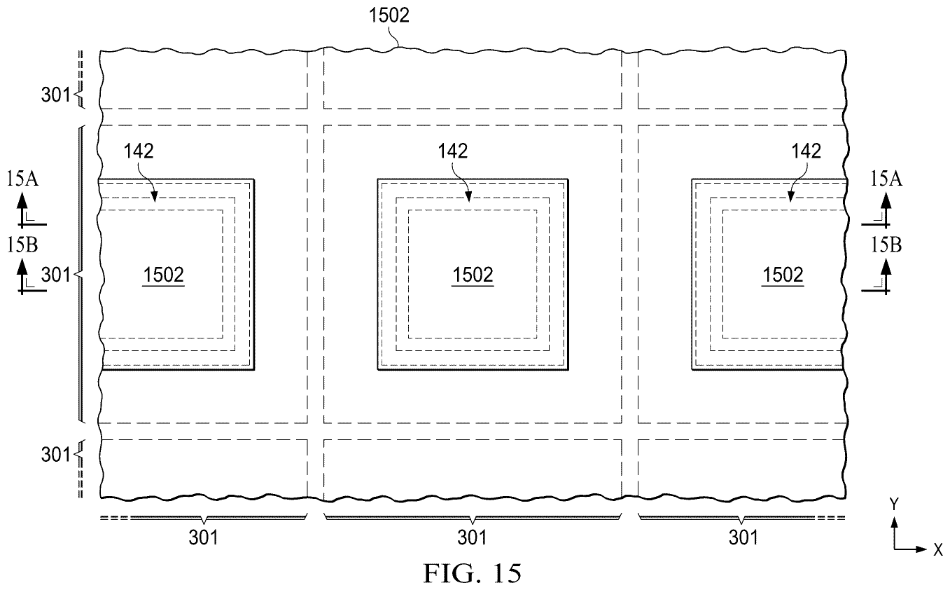

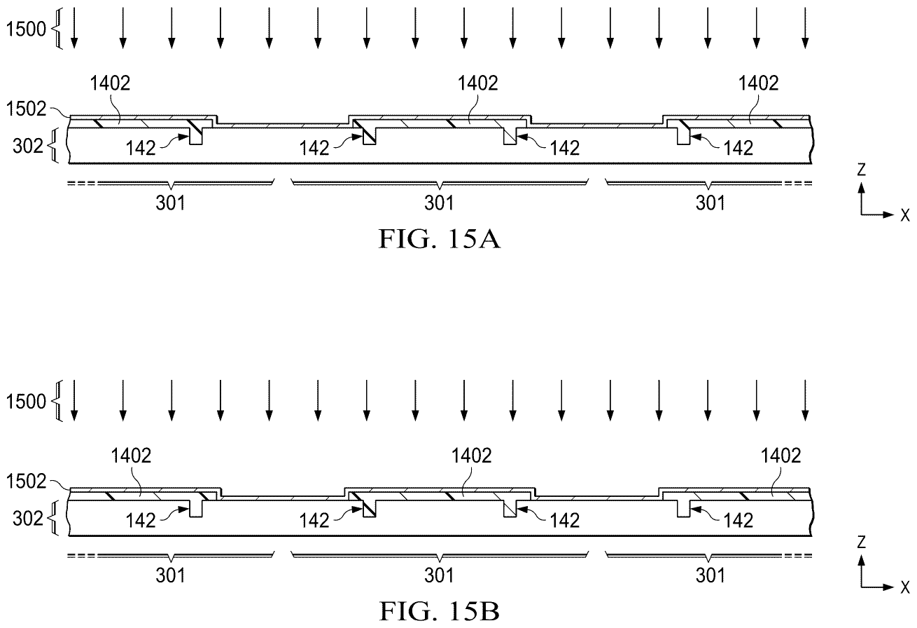

This example continues with die cap formation in FIGS. 15-19B. FIGS. 15-15B show one example, in which a deposition process 1500 is performed that forms a metal seed layer 1502 along the previously formed and patterned sacrificial material layer 1402 and along the top side of the wafer 302 in the spaces between the sacrificial material portions 1402. FIG. 15 shows a partial top view of the processed wafer 302 with the metal seed layer 1502, FIG. 15A shows a partial sectional side view of the wafer 302 taken along line 15A-15A of FIG. 15, and FIG. 15B shows a partial sectional side view of the wafer 302 taken along line 15B-15B of FIG. 15. In one example, the deposition process 1500 includes sputter deposition of nickel or other suitable metal barrier or seed layer material without requiring any deposition mask to form a thin layer of metal 1502 that extends on the top side of the wafer 302 and on the patterned sacrificial photo resist 1402.

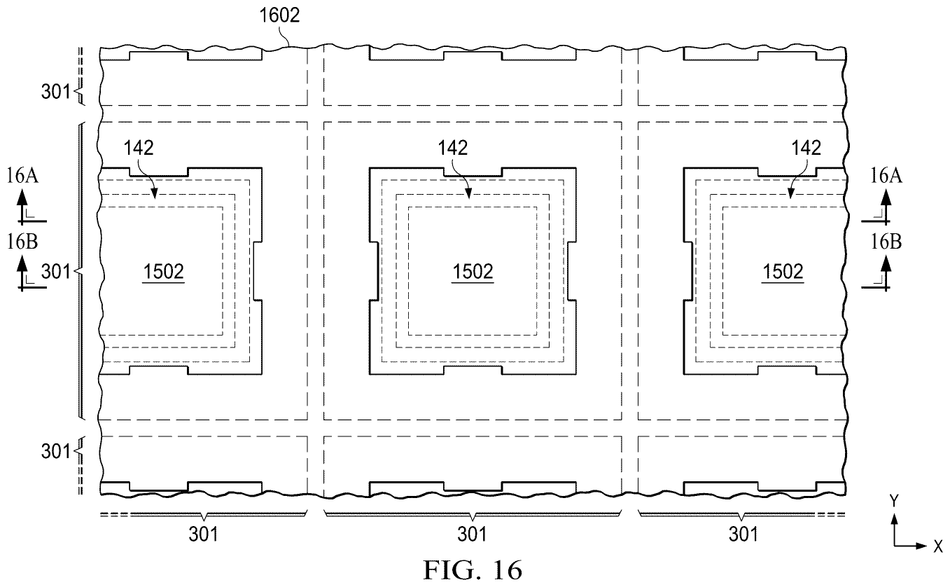

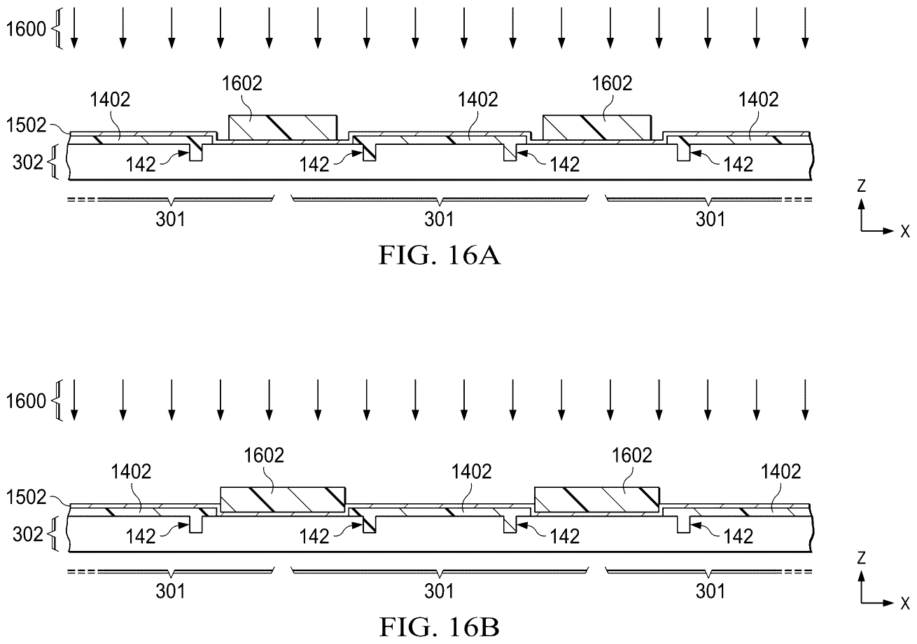

This example continues in FIGS. 16-16B with a process 1600 that forms a first deposition mask 1602 with different spacings along the respective section lines 16A-16A and 16B-16B of FIG. 16. FIG. 16 shows a partial top view of the processed wafer 302, FIG. 16A shows a partial sectional side view of the wafer 302 taken along line 16A-16A of FIG. 16, and FIG. 16B shows a partial sectional side view of the wafer 302 taken along line 16B-16B of FIG. 16. The process 1600 forms the deposition mask 1602 having different dimensions along the two sectional views of FIGS. 16A and 16B to accommodate the formation of the sidewall openings for the illustrated example die cap, where the portions of the sidewall or second cap portion (e.g., 127 above) are to be wider along the edge portions (FIG. 16A) and slightly narrower in the interior portions where a slot opening 123 is to be formed (FIG. 16B).

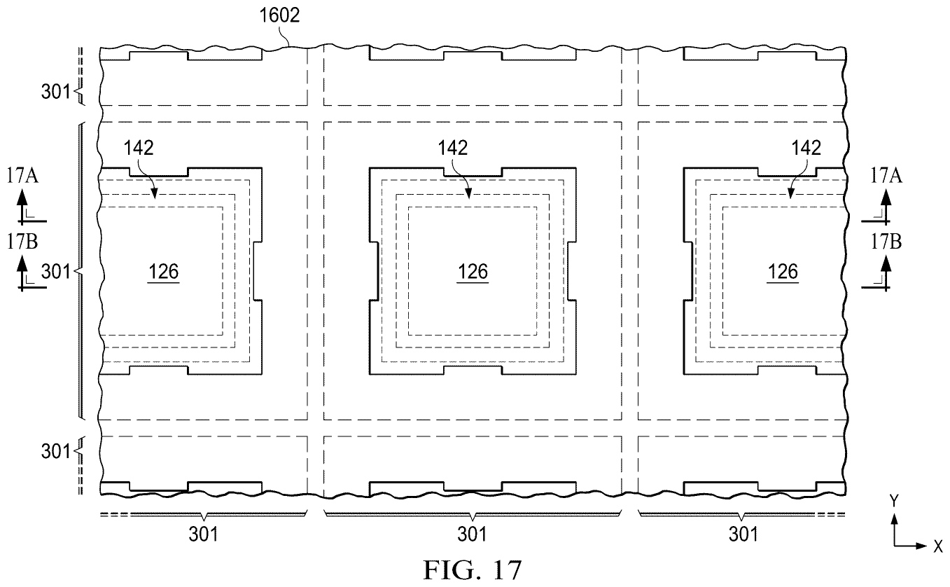

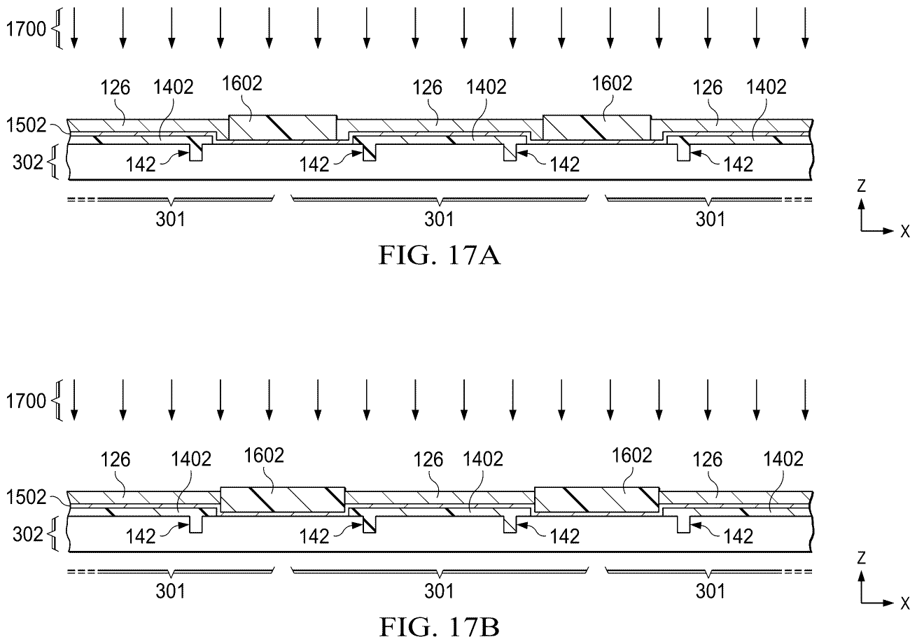

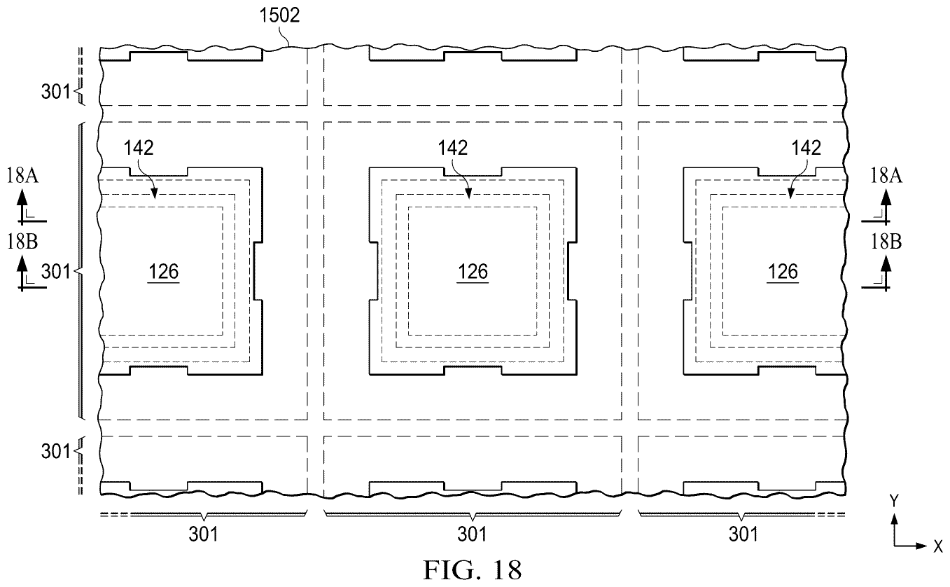

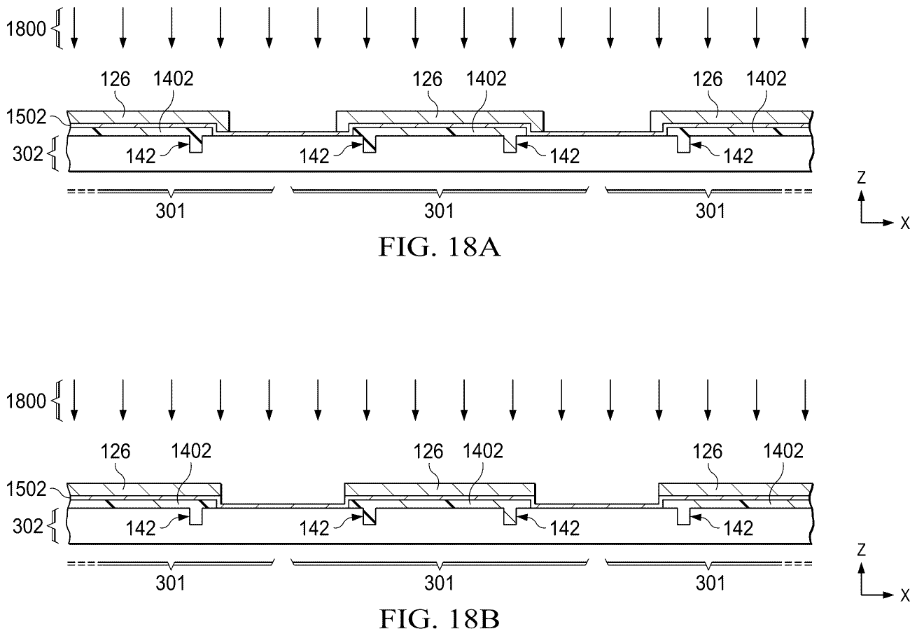

This implementation of the method 200 continues at 204 in FIG. 2 with forming the cap 126 on the sacrificial material layer 1402 as shown in FIGS. 17-18B. FIGS. 17-17B show one example deposition process to deposit nickel using the deposition mask 1602. FIG. 17 shows a partial top view of the processed wafer 302, FIG. 17A shows a partial sectional side view of the wafer 302 taken along line 17A-17A of FIG. 17, and FIG. 17B shows a partial sectional side view of the wafer 302 taken along line 17B-17B of FIG. 17. In one example, the deposition process 1700 is an electroplating process or other suitable metal deposition process that forms the nickel cap 126 over the exposed portions of the patterned sacrificial material layer 1402 and any portions of the seed layer 1502 exposed by the deposition mask 1602. The electroplating deposition process 1700 is performed in one example to deposit the first and second portions of the nickel cap 126 to a thickness or respective thicknesses corresponding to the desired die cap thickness along the third direction Z.

Continuing in FIGS. 18-18B, the deposition mask 1602 is then removed, for example, by a mask removal process 1800 that leaves the patterned cap 126 and portions of the sacrificial material layer 1402 that are exposed through the opening or openings 123 of the cap 126. FIGS. 18-18B show one example of another photo resist strip process 1800, where FIG. 18 shows a partial top view of the processed wafer 302, FIG. 18A shows a partial sectional side view of the wafer 302 taken along line 18A-18A of FIG. 18, and FIG. 18B shows a partial sectional side view of the wafer 302 taken along line 18B-18B of FIG. 18. The mask removal (photo resist strip) process 1800 removes the deposition mask and leaves the patterned cap 126 and exposed portions of the sacrificial material layer 1402 as well as the previously covered portions of the seed layer 1502.

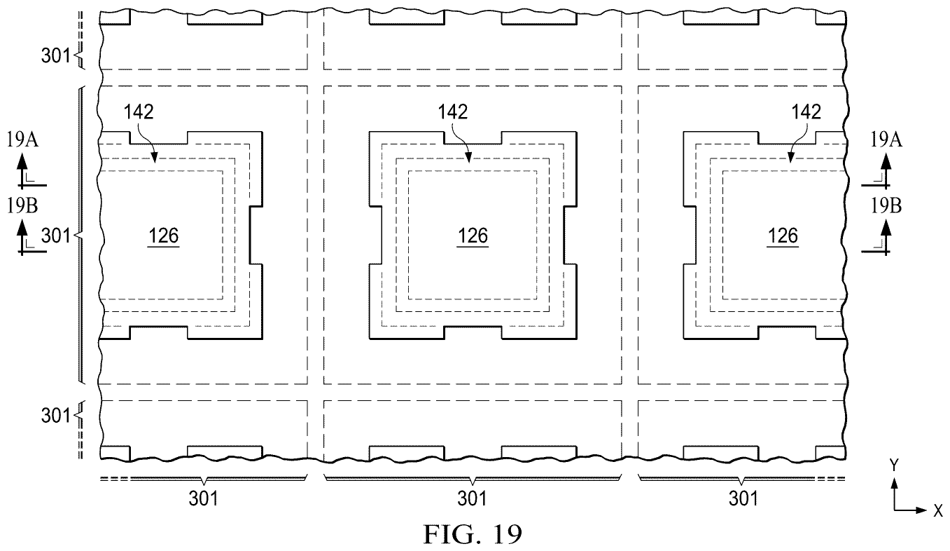

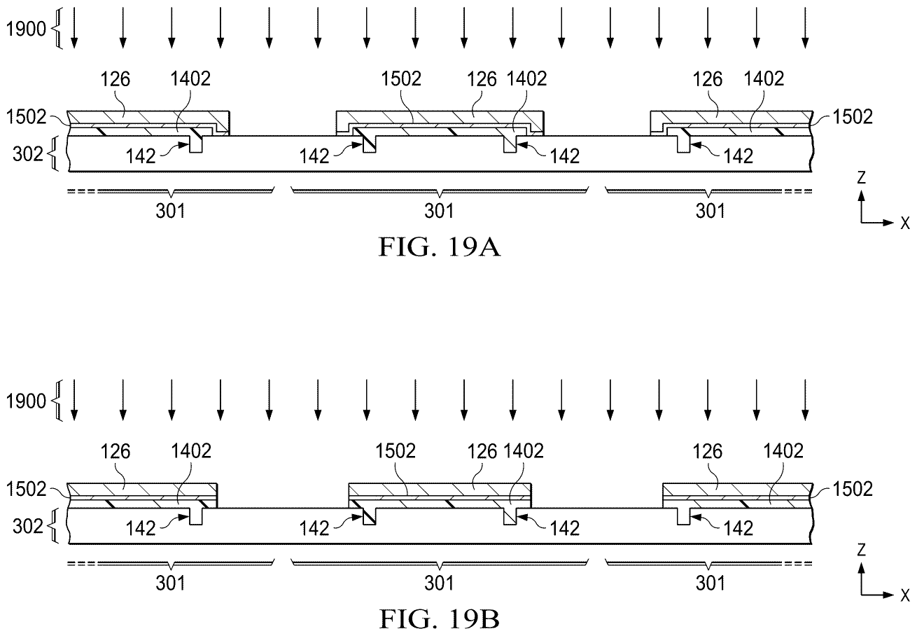

This example continues in FIGS. 19-19B with removal of remaining exposed portions of the metal seed layer 1502, for example, by an etch process 1900. FIGS. 19-19B show one example of a seed layer etch process 1900 that removes the seed layer portions 1502 between the patterned die caps 126 along the top side of the wafer 302, leaving portions of the seed layer 1502 underneath the sidewall or second portions 127 of the cap 126. FIG. 19 shows a partial top view of the processed wafer 302, FIG. 19A shows a partial sectional side view of the wafer 302 taken along line 19A-19A of FIG. 19, and FIG. 19B shows a partial sectional side view of the wafer 302 taken along line 19B-19B of FIG. 19 following the seed layer etch process 1900.

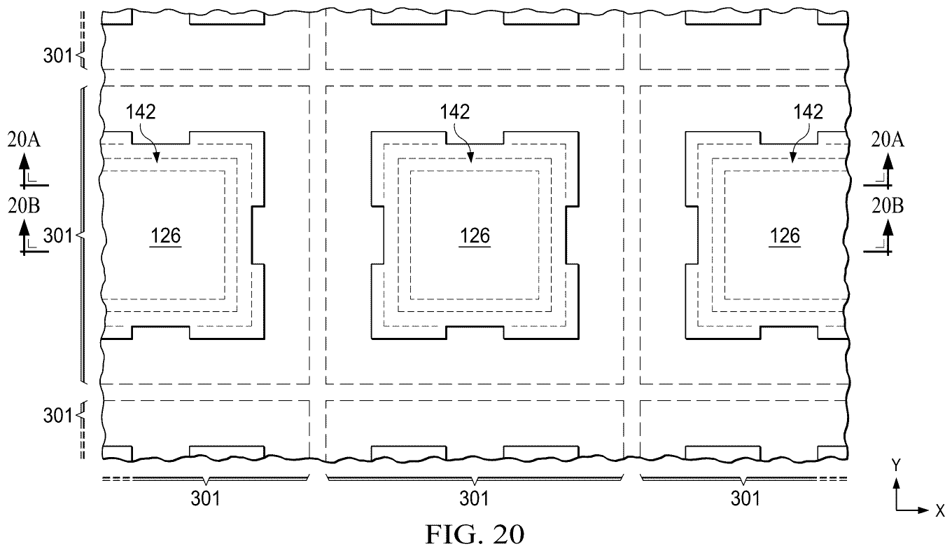

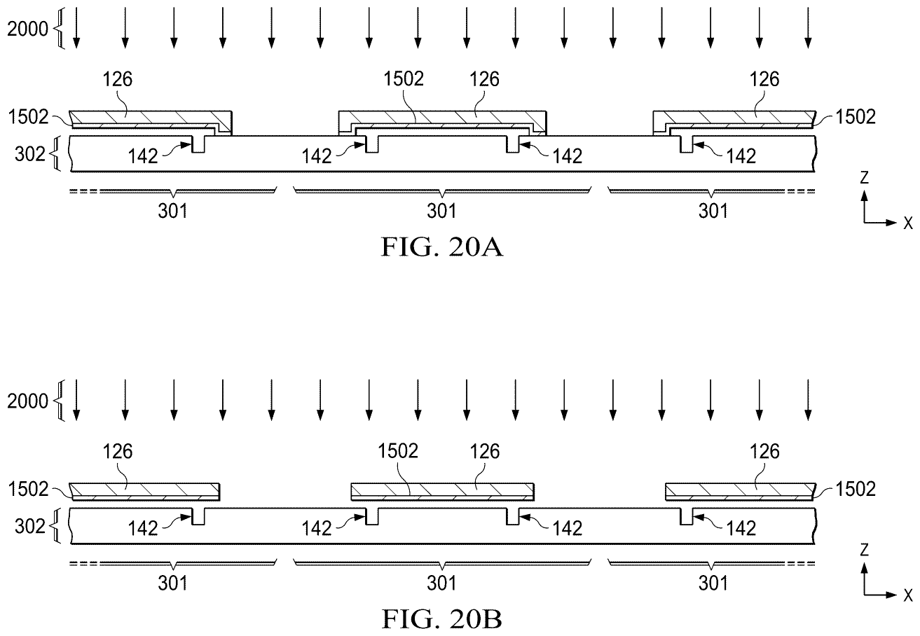

The method 200 in this implementation continues at 205 in FIG. 2 with processing to remove the photo resist sacrificial material. FIGS. 20-20B show one example of a resist strip process 2000, where FIG. 20 shows a partial top view of the processed wafer 302, FIG. 20A shows a partial sectional side view of the wafer 302 taken along line 20A-20A of FIG. 20, and FIG. 20B shows a partial sectional side view of the wafer 302 taken along line 20B-20B of FIG. 20. The resist strip 2000 in one example is highly selective to the photo resist sacrificial material and operates to remove the sacrificial resist from under the cap 126 through the opening or openings 123 of the nickel die cap 126 and leaves the electroplated nickel die cap structure 126 with the cavity defined by the space from which the sacrificial copper was removed via the openings 123 through the desired portions of the nickel material 126. The sizing, number, and positioning of the opening or openings 123 can be adjusted to facilitate the resist stripping process 2000 in consideration of the final structural rigidity of the cap 126 as well as any considerations related to preventing or mitigating ingress of mold compound of the device package structure (e.g., 108 above) and/or ingress of any included seal film 129.

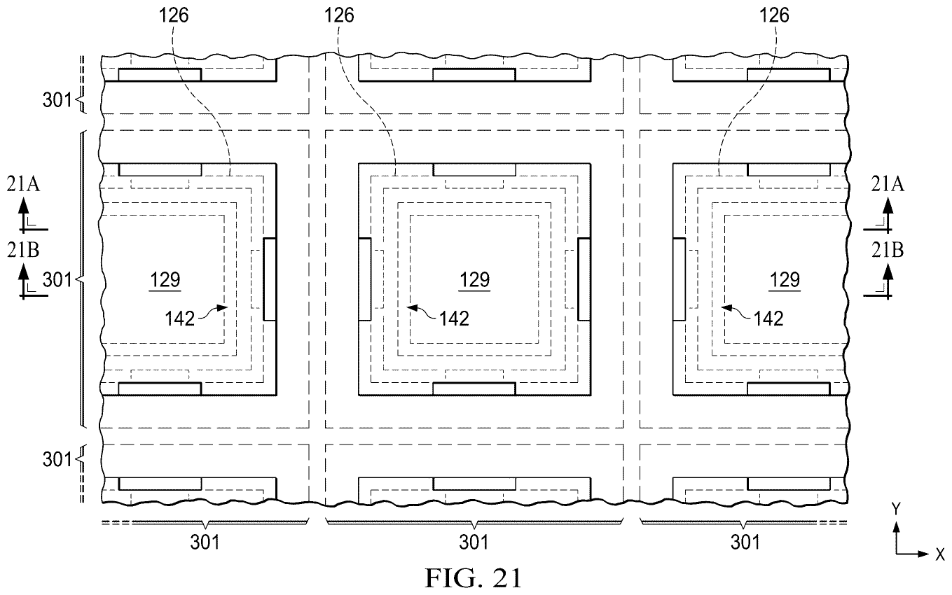

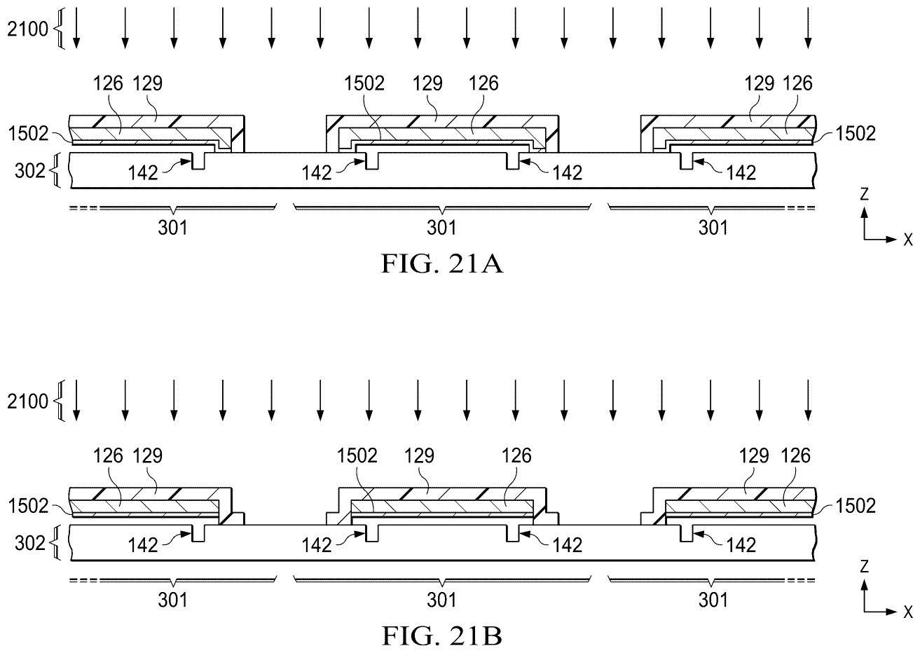

The method 200 in this implementation continues at 206 in FIG. 2 with optional die coat film formation. FIGS. 21-21B show one example, in which a process 2100 is performed that deposits and patterns or otherwise selectively forms the die coat film 129 over the cap 126 in each unit area 301 of the wafer 302. FIG. 21A shows a partial sectional side view of the wafer 302 taken along line 21A-21A of FIG. 21, and FIG. 21B shows a partial sectional side view of the wafer 302 taken along line 21B-21B of FIG. 21. In one implementation, the die coat film 129 seals the opening or openings 123 of the cap 126. In another implementation, the die coat film formation at 206 can be omitted.

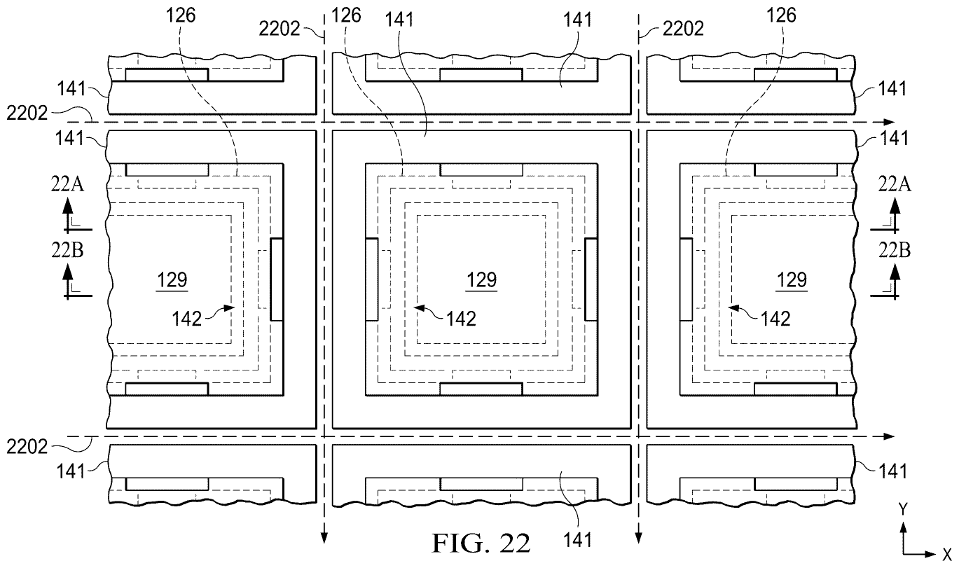

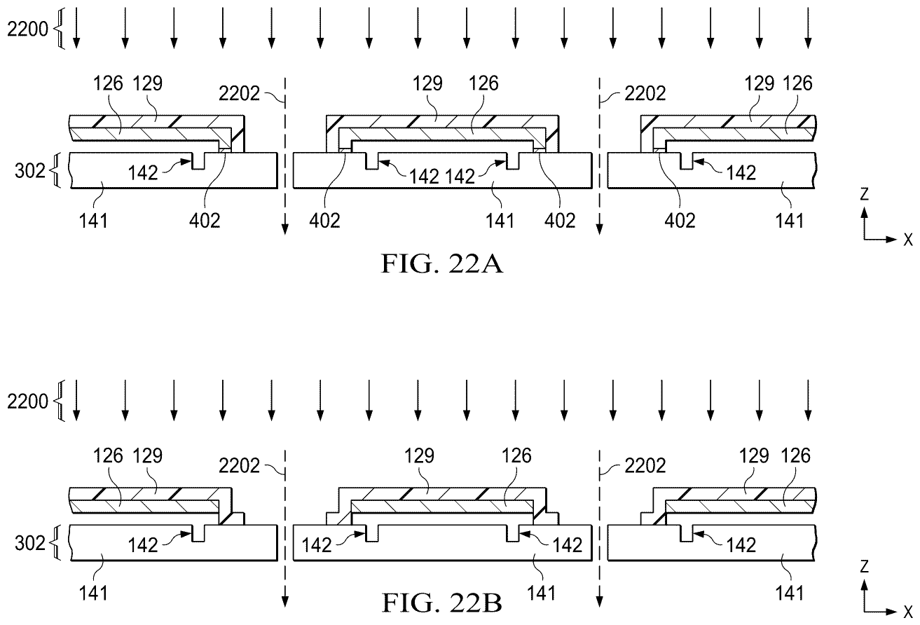

The method 200 continues with die singulation processing at 207 in FIG. 2 after the above described processing using either the copper metal sacrificial material layer (FIGS. 4-13B) or using the photo resist sacrificial material layer (FIGS. 14-21B). FIGS. 22-22B illustrate one example, in which a die singulation or separation process 2200 is performed that separates individual semiconductor dies 141 from the processed wafer 302 along separation lines 2202 (e.g., along rows of the first direction X and columns along the second direction Y as shown in FIG. 22. In one implementation, the die singulation process includes one or more of saw cutting, laser cutting, chemical etching, mechanical separation using a dicing tape or combinations thereof, etc.

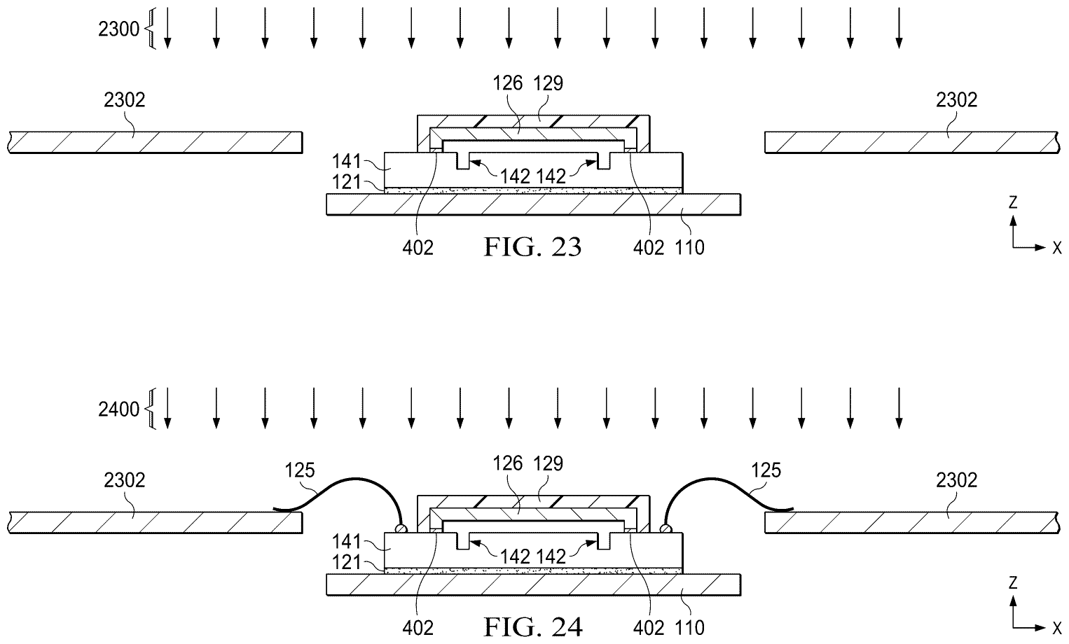

The method 200 continues in one example with die attach processing at 208. FIG. 23 shows one example, in which a die attach process 2300 is performed that attaches the bottom or backside of an individual semiconductor die 141 on a corresponding die attach pad 110 in each unit area of a starting lead frame panel array structure 2302 having rows and columns of individual unit areas that correspond to a prospective packaged electronic device. The die attach process 2300 can include dispensing the die attach film or adhesive 121 onto the top side of the respective die attach pads 110 in each panel array unit area, followed by placement of the semiconductor die 141 with the back side thereof engaging the die attach film adhesive 121, for example, using automated pick and place equipment (not shown). The die attach processing 2300 in one example can include die attach adhesive curing, such as by thermal heating, UV exposure, etc.

The illustrated example also includes electrical connection at 210 in FIG. 2. FIG. 24 shows one example, in which a wire bonding process 2400 is performed that forms the above described bond wires 125 to provide interconnections in each unit area of the lead frame panel array. In other implementations, different forms or types of electrical interconnection processing can be performed, such as flip chip die attach soldering, other wire bonding, or combinations thereof, etc.

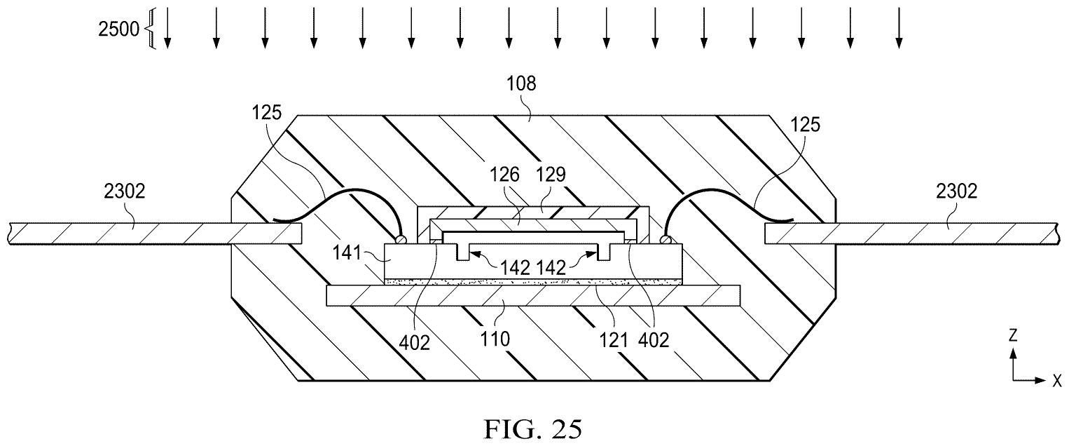

The method 200 in one example continues at 211 in FIG. 2 with molding to form the above-described package structure 108. FIG. 25 shows one example, in which a molding process 2500 is performed using a mold (not shown). The molding process 2500 forms the illustrated molded package structure 108 that encloses the die attach pad 110, the semiconductor die for 11 with the cap 126, and the bond wires 125, although not a requirement of all possible implementations. The illustrated molding process 2500, moreover, leaves outer portions of the lead frame 2302 exposed outside the molded package structure 108 as shown in FIG. 25.

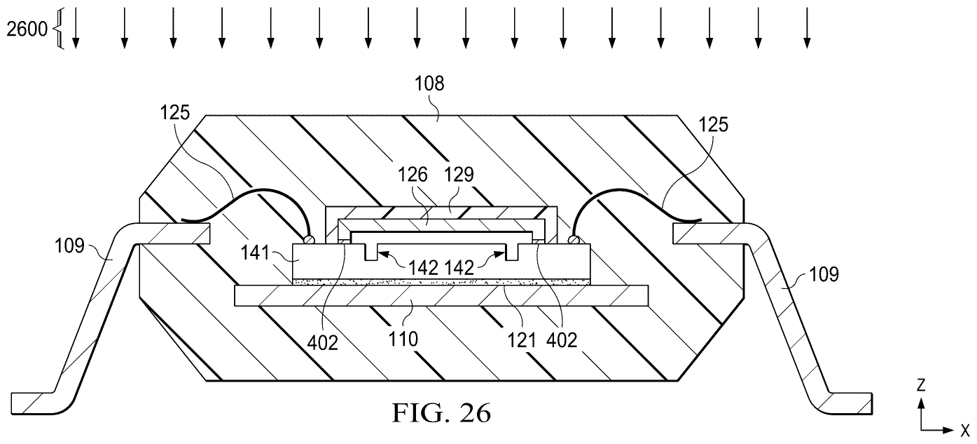

The method 200 in FIG. 2 continues at 212 with package separation. FIG. 26 shows one example, in which the conductive metal leads 109 of the starting lead frame panel array structure 2302 are trimmed and formed in a process 2600 using suitable cutting and/or punch press equipment (not shown) to form the leads 109 that can be soldered to a host circuit board (e.g., FIGS. 1-1C above).

Modifications are possible in the described embodiments, and other embodiments are possible, within the scope of the claims.

1. An electronic device, comprising:
a semiconductor die having a side; and
a cap including a first portion spaced apart from the side of the semiconductor die to define a cavity over a portion of the side of the semiconductor die, and a second portion attached to the side of the semiconductor die and extending from the side of the semiconductor die to the first portion, wherein one of the first and second portions has an opening.

2. The electronic device of claim 1, wherein the cap includes a metal material.

3. The electronic device of claim 2, wherein the metal material of the cap includes nickel.

4. The electronic device of claim 1, further comprising a seal film that seals the opening.

5. The electronic device of claim 4, wherein the seal film includes polyimide.

6. The electronic device of claim 1, wherein:
the second portion extends from the side of the semiconductor die to a periphery of the first portion; and
the cap further includes a support pillar extending from the side of the semiconductor die to an interior of the first portion, the support pillar spaced apart from the second portion of the cap.

7. The electronic device of claim 1, wherein the first portion of the cap includes a round opening that is spaced apart from a periphery of the first portion.

8. The electronic device of claim 7, wherein the second portion of the cap includes a slot opening.

9. The electronic device of claim 1, wherein the second portion of the cap includes a slot opening.

10. The electronic device of claim 1, further comprising a bond wire coupled to a conductive feature on the side of the semiconductor die.

11. The electronic device of claim 1, further comprising a package structure that encloses the semiconductor die and the cap.

12. A system, comprising:
a circuit board having a conductive feature; and
an electronic device, including:
a conductive terminal that is soldered to the conductive feature of the circuit board;
a semiconductor die having a side; and
a cap including a first portion spaced apart from the side of the semiconductor die to define a cavity over a portion of the side of the semiconductor die, and a second portion attached to the side of the semiconductor die and extending from the side of the semiconductor die to the first portion, wherein one of the first and second portions has an opening.

13. The system of claim 12, wherein the cap includes a metal material.

14. The system of claim 12, wherein the electronic device further comprises a seal film that seals the opening.

15. The system of claim 12, wherein:
the second portion extends from the side of the semiconductor die to a periphery of the first portion; and
the cap further includes a support pillar extending from the side of the semiconductor die to an interior of the first portion, the support pillar spaced apart from the second portion of the cap.

16. A method of fabricating an electronic device, the method comprising:
forming a patterned sacrificial material layer on a side of a semiconductor wafer;
forming a cap with an opening on the patterned sacrificial material layer;
removing the patterned sacrificial material layer from under the cap;
separating a semiconductor die with the cap from the semiconductor wafer; and
packaging the semiconductor die to form an electronic device.

17. The method of claim 16, further comprising, after removing the patterned sacrificial material layer, forming a seal film on a portion of the cap to seal the opening.

18. The method of claim 16, wherein the patterned sacrificial material layer includes a metal material.

19. The method of claim 16, wherein the patterned sacrificial material layer includes a photo resist material.

20. The method of claim 16, further comprising forming a metal seed layer on the side of the semiconductor wafer before forming the patterned sacrificial material layer.

21. The method of claim 16, further comprising forming a metal seed layer on the patterned sacrificial material layer.

22. The method of claim 16, wherein forming the cap includes forming a support pillar extending from the side of the semiconductor wafer to an interior of a first portion of the cap.
